(19) United States
(12) Patent Application Publication
(10) Pub. No.: US 2017/0278460 A1
(43) Pub. Date: Sep. 28, 2017

(54) SEMICONDUCTOR CIRCUIT FOR DIGITAL-ANALOG CONVERSION AND IMPEDANCE CONVERSION

(71) Applicant: Synaptics Japan GK, Tokyo (JP)

(72) Inventor: Toshiyuki HIKICHI, Tokyo (JP)

(21) Appl. No.: 15/463,859

(22) Filed: Mar. 20, 2017

(30) Foreign Application Priority Data
Mar. 23, 2016 (JP) 2016059180

(51) Int. Cl. G09G 3/3266; G09G 3/36; H03M 1/66

(52) U.S. Cl. CPC G09G 3/3266; H03M 1/66; G09G 3/3677; G09G 2310/027

(57) ABSTRACT

A semiconductor circuit includes first and second DA converters which selects first and second reference voltages in response to upper m bits of input digital data, a select circuitry which outputs first to N-th selected input voltages in response to lower n bits of the input digital data; first to N-th differential input stages, an output stage and a first tail current source. Each of the first to N-th differential input stages includes a transistor pair. The i-th selected input voltage is supplied to the gates of a first MISFET of the i-th differential input stage and the gates of the second MISFETs of the first to N-th differential input stages are connected to the output node. The first tail current source controls the current levels of the first tail current in the first to N-th differential input stages in response to lower n bits of the input digital data.

### CROSS REFERENCE

This application claims priority to Japanese Patent Application No. 2016-059180, filed on Mar. 23, 2016, the disclosure of which is incorporated herein by reference in its entirety.

### TECHNICAL FIELD

The present disclosure relates to a semiconductor circuit and display driver incorporating the same, more particularly, to a semiconductor circuit having the functions of digital-analog conversion and impedance conversion.

### BACKGROUND ART

The DA (digital-analog) converter, which is a circuit configured to receive an input digital data and output an analog output signal having a signal level corresponding to the value of the input digital data, is one of the circuits most commonly used in semiconductor integrated circuits. A typical type of DA converter is configured to receive a set of reference voltages different from each other, select one corresponding to the value of an input digital data from among the reference voltages and output the selected reference voltage as the analog output voltage. The reference voltages supplied to a DA converter are generated by using a resistor string, for example.

One requirement of recent DA converters is to have a higher resolution, that is, to be able to generate an analog output signal corresponding to an input digital data with an increased bit depth. For example, a panel display device configured to supply drive voltages corresponding to image data to a display panel, such as a liquid crystal display device and an OLED (organic light emitting diode) display device, often requires integrating DA converters with a higher resolution within the display driver which drives the display panel, in order to be adapted to an increased number of displayable colors.

A DA converter with a high resolution, however, suffers from increase in the circuit size. One typical approach for providing a DA converter with a higher resolution is to increase the number of reference voltages supplied to the DA converter. The increase in the number of reference voltages, however, undesirably increases the circuit size of a circuitry which supplies the reference voltages to the DA converter and also increases the circuit size of the selector which selects the analog output voltage from the increased number of reference voltages. The increase in the circuit size of a DA converter undesirably causes a higher cost. This problem is especially significant in an integrated circuit which incorporates therein an increased number of DA converters. One example of such integrated circuit is a display driver which drives a display panel.

It should be noted that Japanese patent application publication No. 2015-211266 A discloses the configuration of a differential amplifier circuit used in a display driver which drives a display panel.

### SUMMARY

In view of the background described above, a differential amplifier circuit may be connected to a DA converter with the function of digital-analog conversion. In an actual implementation of a semiconductor circuit, a circuit configuration in which the output of a DA converter is connected to a differential amplifier circuit to achieve impedance conversion is often used, because a DA converter usually has a large output impedance. In such circuit configuration, a high resolution can be achieved as a whole by giving the differential amplifier circuit the function of digital-analog conversion. For example, when a differential amplifier circuit having the function of performing n-bit digital-analog conversion is connected to a DA converter adapted to m-bit input digital data, this allows performing digital analog conversion on (m+n)-bit input image data as a whole. This circuit configuration may be advantageous for suppressing an increase in the circuit size.

According to techniques described herein, a higher resolution and a reduced circuit size may be achieved at the same time with respect to a semiconductor circuit in which a differential amplifier circuit having the function of digital-analog conversion is connected to the output of a DA converter.

Therefore, an objective of the present disclosure is to provide a technique for achieving a high resolution and a reduced circuit size at the same time with respect to a semiconductor circuit having the functions of digital-analog conversion and impedance conversion. Other objectives and new features of the present disclosure would be understood by a person skilled in the art from the disclosure given below.

In one embodiment, a semiconductor circuit includes: a first DA converter configured to receive a plurality of reference voltages and select a first reference voltage from the plurality of reference voltages in response to upper m bits of (m+n)-bit digital input data; a second DA converter configured to receive the plurality of reference voltages and select a second reference voltage from the plurality of reference voltages in response to the upper m bits of the (m+n)-bit digital input data, the second reference voltage being lower than the first reference voltage; a select circuitry configured to receive the first and second reference voltages and output first to N-th selected input voltages in response to lower n bits of the input digital data, each of the first to N-th selected input voltages being selected as one of the first and second reference voltages and N being an integer of two or more; first to N-th differential input stages; first and second drain interconnections; an output stage configured to output an analog output voltage to an output node in response to currents flowing through the first and second drain interconnections; and a first tail current source. Each of first to N-th differential input stages includes: a first MISFET of a first conductivity type, having a source connected to a first node and a drain connected to the first drain interconnection; and a second MISFET of the first conductivity type, having a source connected to the first node and a drain connected to the second drain interconnection. The i-th selected input voltage of the first to N-th selected input voltages is supplied to a gate of the first MISFET of the i-th differential input stage of the first to N-th differential input stages, i being an integer from one to N. The gate of the second MISFET of each of the first to N-th differential input stages is connected to the output node. The first tail current source is configured to generate a first tail current flowing through the first node of each of the first to N-th differential input stages. The first tail current source is configured to control the current level of the first tail current generated on the first node of each of the first to N-th differential input stages in response to the lower n-bits of the input digital data.

The semiconductor thus configured is preferably used in a display driver which drives source lines of a display panel in response to image data. In one embodiment, the above-described semiconductor circuit may be integrated in a source driver circuit of the display driver, which generates source voltages supplied to the source lines. In another embodiment, the above-described semiconductor circuit may be used as a preamplifier of a reference voltage generator circuit which supplies a set of reference voltages to the source driver circuit.

The present disclosure provides a technique for achieving a high resolution and a reduced circuit size at the same time with respect to a semiconductor circuit having the functions of digital-analog conversion and impedance conversion.

### BRIEF DESCRIPTION OF THE DRAWINGS

The above and other advantages and features of the present disclosure will be more apparent from the following description taken in conjunction with the accompanied drawings, in which:

FIG. 1 is a circuit diagram illustrating the configuration of a semiconductor circuit in one embodiment;

FIG. 2 is a circuit diagram illustrating the configuration of a differential amplifier circuit in one embodiment;

FIG. 3 is a circuit diagram illustrating one example of the configuration of a tail current source circuit;

FIG. 4 is a table illustrating one example of the operation of the semiconductor circuit in the present embodiment;

FIG. 5 is a circuit diagram illustrating the configuration of a tail current source circuit in a modification of the present embodiment;

FIG. 6 is a circuit diagram illustrating the configuration of a differential amplifier circuit in which each differential input stage includes only a PMOS differential pair in one embodiment;

FIG. 7 is a circuit diagram illustrating the configuration of a differential amplifier circuit in which each differential input stage includes only an NMOS differential pair in one embodiment;

FIG. 8A is a circuit diagram illustrating the configuration of a semiconductor circuit in a modification in which a differential amplifier circuit includes four differential input stages;

FIG. 8B is a circuit diagram illustrating one example of the configuration of a differential amplifier circuit which includes four differential input stages;

FIG. 9 is a circuit diagram illustrating one example of the configuration of a tail current source in the case when a differential amplifier circuit includes four differential input stages;

FIG. 10 is a circuit diagram illustrating one example of the configuration of a differential amplifier circuit which includes four differential input stages, two of which include only a PMOS differential pair and the other two of which include only an NMOS differential pair;

FIG. 11 is a block diagram schematically illustrating the configuration of a panel display device in one embodiment;

FIG. 12 is a block diagram schematically illustrating the configuration of a display driver;

FIG. 13 is a circuit diagram illustrating one example of a drive circuitry of the display driver; and

FIG. 14 is a circuit diagram illustrating the configuration of a tournament circuit of a gamma circuit (reference voltage generator circuit) in one embodiment.

### DETAILED DESCRIPTION OF PREFERRED EMBODIMENTS

Various embodiments of the present disclosure will be now described herein with reference to attached drawings. It should be noted that same or similar elements may be denoted by same or corresponding reference numerals and suffixes may be attached to reference numerals for distinguishing multiple same components from each other.

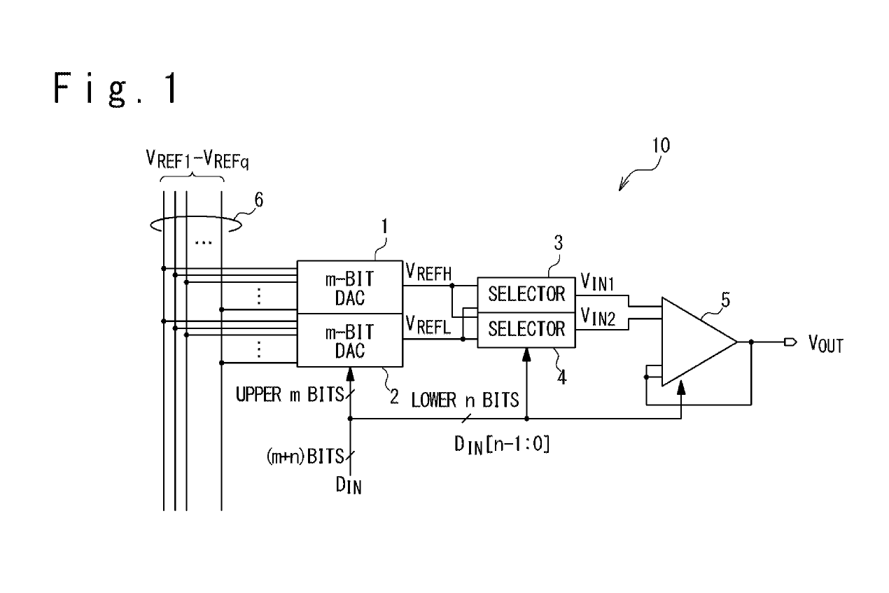

FIG. 1 is a circuit diagram illustrating the configuration of a semiconductor circuit 10 in one embodiment. The semiconductor circuit 10 has the functions of digital-analog conversion and impedance conversion. More specifically, the semiconductor circuit 10 is configured to receive input digital data D_{IN} and generate an analog output voltage V_{OUT} having a voltage level corresponding to the value of the input digital data D_{IN}. In the present embodiment, the input digital data D_{IN} is an (m+n)-bit data for m and n being natural numbers, and the semiconductor circuit 10 is configured to output the analog output voltage VOUT having a selected one of 2^{(m+n)} different voltages levels. In other words, the semiconductor circuit 10 has a resolution of (m+n) bits.

In the present embodiment, the semiconductor circuit 10 includes DA converters 1, 2, selectors 3, 4 and a differential amplifier circuit 5.

The DA converters 1 and 2 is each configured to select one of reference voltages V_{REF1} to V_{REFq} received from a reference voltage bus 6 in response to upper m bits of the input digital data D_{IN} and output the selected reference voltage, where q is the number of the reference voltages V_{REF1} to V_{REFq} supplied to the DA converters 1 and 2. In the present embodiment, q is 2^{m}+1. In the following, the reference voltage selected by the DA converter 1 is referred to as the reference voltage V_{REFH} and the reference voltage selected by the DA converter 2 is referred to as the reference voltage V_{REFL}. The DA converters 1 and 2 are configured to select the reference voltages V_{REFH} and V_{REFL} so that the reference voltages V_{REFH} and V_{REFL} are different from each other and the reference voltages V_{REFH} is higher than the reference voltages V_{REFL}.

In one embodiment, the reference voltages V_{REF1} to V_{REFq} are generated to satisfy the following formula:

V_{REF1}<V_{REF2}< . . . <V_{REF(q-1)}<V_{REFq}.

In this case, two reference voltages V_{REFk} and V_{REF(k+1)}, which have adjacent voltage levels, may be selected from the reference voltages V_{REF1} to V_{REFq} as the reference voltages V_{REFH} and V_{REFL}, where k is an integer from one to q−1. As described later, the semiconductor circuit 10 is configured to generate the analog output voltage V_{OUT} so that the analog output voltage V_{OUT} is equal to or higher than the reference voltage V_{REFL} and lower than the reference voltage V_{REFH}.

The selectors 3 and 4 operate as a select circuitry which receives the reference voltages V_{REFH} and V_{REFL} and outputs selected input voltages V_{IN1} and V_{IN2} to be supplied to the differential amplifier circuit 5, in response to lower n bits of the input digital data D_{IN}. It should be noted that each of the selected input voltages V_{IN1} and V_{IN2} is selected from the reference voltages V_{REFH} and V_{REFL}. The selector 3 outputs a selected one of the reference voltages V_{REFH} and V_{REFL} as the selected input voltage V_{IN1}, in response to the lower n bits of the input digital data D_{IN}. The selector 4 outputs a selected one of the reference voltages V_{REFH} and V_{REFL} as the selected input voltage V_{IN2}, in response to the lower n bits of the input digital data D_{IN}. It should be noted that the selected input voltages V_{IN1} and V_{IN2} selected by the selectors 3 and 4 may be equal to each other.

The differential amplifier circuit 5 is configured to receive the selected input voltages V_{IN1} and V_{IN2} from the selectors 3 and 4 and generate the analog output voltage V_{OUT} from the selected input voltages V_{IN1} and V_{IN2}. It should be noted that, as described later in detail, the voltage level of the analog output voltage V_{OUT} output from the differential amplifier circuit 5 is adjusted in response to the value of the lower n bits of the input digital data D_{IN}.

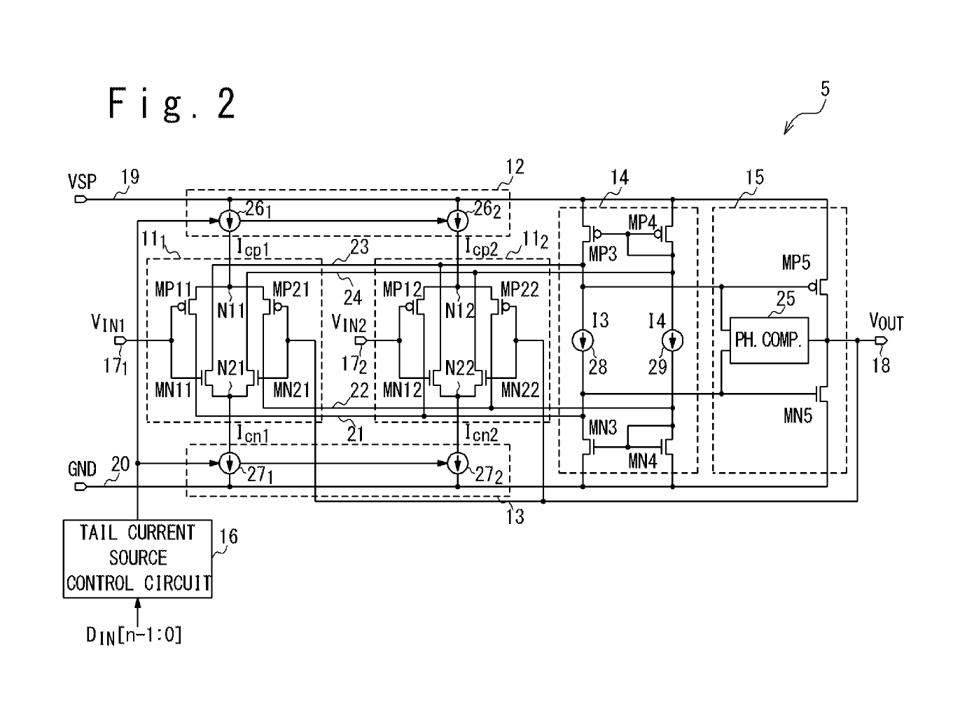

FIG. 2 is a circuit diagram illustrating the configuration of the differential amplifier circuit 5 in one embodiment. The differential amplifier circuit 5 includes a pair of differential input stages 11₁, 11₂, a pair of tail current source circuits 12, 13, an active load circuit 14, an output stage 15 and a tail current source control circuit 16. The differential amplifier circuit 5 receives the selected input voltages V_{IN1} and V_{IN2}, which are supplied from the selectors 3 and 4, on the input nodes 17₁ and 17₂, respectively, and outputs the analog output voltage V_{OUT} from the output node 18.

In detail, the differential input stage 11₁ includes PMOS transistors MP11, MP21 and NMOS transistors MN11 and MN21. It should be noted that, as is well known in the art, the NMOS transistor is a sort of N-channel MISFET (metal insulator semiconductor field effect transistor) and the PMOS transistor is a sort of P-channel MISFET.

The PMOS transistors MP11 and MP21 have commonly-connected sources and form a PMOS differential pair. More specifically, the sources of the PMOS transistors MP11 and MP21 are commonly connected to a node N11. The gate of the PMOS transistor MP11 is connected to the input node 17₁, which receives the selected input voltage V_{IN1} from the selector 3, and the gate of the PMOS transistor MP21 is connected to the output node 18, from which the analog output voltage V_{OUT} is output. The drain of the PMOS transistor MP11 is connected to a drain interconnection 21 and the drain of the PMOS transistor MP21 is connected to a drain interconnection 22.

The NMOS transistors MN11 and MN21 have commonly-connected sources and form an NMOS differential pair. More specifically, the sources of the NMOS transistors MN11 and MN21 are commonly connected to a node N21. The gate of the NMOS transistor MN11 is connected to the input node 17₁, and the gate of the NMOS transistor MN21 is connected to the output node 18. The drain of the NMOS transistor MN11 is connected to a drain interconnection 23 and the drain of the NMOS transistor MN21 is connected to a drain interconnection 24.

The differential input stage 11₂ is configured similarly to the differential input stage 11₁. The differential input stage 11₂ includes PMOS transistors MP12, MP22, and NMOS transistors MN12 and MN22.

The PMOS transistors MP12 and MP22 have commonly-connected sources and form a PMOS differential pair. More specifically, the sources of the PMOS transistors MP12 and MP22 are commonly connected to a node N12. The gate of the PMOS transistor MP12 is connected to the input node 17₂, which receives the selected input voltage V_{IN2} from the selector 4, and the gate of the PMOS transistor MP22 is connected to the output node 18, from which the analog output voltage V_{OUT}. The drain of the PMOS transistor MP12 is connected to a drain interconnection 21 and the drain of the PMOS transistor MP22 is connected to a drain interconnection 22.

The NMOS transistors MN12 and MN22 have commonly-connected sources and form an NMOS differential pair. More specifically, the sources of the NMOS transistors MN12 and MN22 are commonly connected to a node N22. The gate of the NMOS transistor MN12 is connected to the input node 17₂, and the gate of the NMOS transistor MN22 is connected to the output node 18. The drain of the NMOS transistor MN12 is connected to a drain interconnection 23 and the drain of the NMOS transistor MN22 is connected to a drain interconnection 24.

The tail current source circuit 12 supplies tail currents Icp1 and Icp2 to the nodes N11 and N12 of the differential input stages 11₁ and 11₂, respectively. In the present embodiment, the tail current source circuit 12 includes a variable current source 26₁ connected between a positive-side line 19 and the node N11 and a variable current source 26₂ connected between the positive-side line 19 and the node N12. In this embodiment, an analog power supply voltage VSP is supplied to the positive-side line 19. The variable current source 26₁ generates the tail current Icp1 flowing through the node N11 and the variable current source 26₂ generates the tail current Icp2 flowing through the node N12. A control signal is supplied to the tail current source circuit 12 from the tail current source control circuit 16 and the current levels of the tail currents Icp1 and Icp2 are controlled in response to the control signal.

Similarly, the tail current source circuit 13 draws tail currents Icn1 and Icn2 from the nodes N21 and N22 of the differential input stages 11₁ and 11₂, respectively. In the present embodiment, the tail current source circuit 13 includes a variable current source 27₁ connected between the node N21 and a negative-side line 20 and a variable current source 27₂ connected between the node N22 and the negative-side line 20. In this embodiment, the negative-side line 20 is connected to the circuit ground. The variable current source 27₁ generates the tail current Icn1 flowing through the node N21 and the variable current source 27₂ generates the tail current Icn2 flowing through the node N22. A control signal is supplied to the tail current source circuit 13 from the tail current source control circuit 16 and the current levels of the tail currents Icn1 and Icn2 are controlled in response to the control signal.

The active load circuit 14 operates as an active load connected to the drain interconnections 21 to 24. In the present embodiment, the active load circuit 14 includes PMOS transistors MP3, MP4, NMOS transistors MN3, MN4 and constant current sources 28 and 29.

The PMOS transistors MP3 and MP4 form a current mirror connected to the drain interconnections 23 and 24. The PMOS transistors MP3 and MP4 have sources commonly connected to the positive-side line 19 and gates commonly connected to the drain of the PMOS transistor MP4. The drains of the PMOS transistors MP3 and MP4 are connected to the drain interconnections 23 and 24, respectively.

The NMOS transistors MN3 and MN4 form a current mirror connected to the drain interconnections 21 and 22. The NMOS transistors MN3 and MN4 have sources commonly connected to the negative-side line 20 and gates commonly connected to the drain of the NMOS transistor MN4. The drains of the NMOS transistors MN3 and MN4 are connected to the drain interconnections 21 and 22, respectively.

The current source 28 is connected between the drain of the PMOS transistor MP3 and the drain of the NMOS transistor MN3, and generates a current flowing from the drain of the PMOS transistor MP3 to the drain of the NMOS transistor MN3. Similarly, the current source 29 is connected between the drain of the PMOS transistor MP4 and the drain of the NMOS transistor MN4, and generates a current flowing from the drain of the PMOS transistor MP4 to the drain of the NMOS transistor MN4.

The output stage 15 drives the output node 18 in response to the currents flowing through the drain interconnections 21 to 24. In the present embodiment, the output stage 15 includes a PMOS transistor MP5, an NMOS transistor MN5 and a phase compensation circuit 25. The PMOS transistor MP5 and the NMOS transistor MN5 operate as output transistors which drive the output node 18. The PMOS transistor MP5 has a source connected to the positive-side line 19, a drain connected to the output node 18 and a gate connected to the drain of the PMOS transistor MP3 of the active load circuit 14. The NMOS transistor MN5 has a source connected to the negative-side line 20, a drain connected to the output node 18 and a gate connected to the drain of the NMOS transistor MN3 of the active load circuit 14. The phase compensation circuit 25 is connected to the gate of the PMOS transistor MP5, the gate of the NMOS transistor MN5 and the output node 18 to achieve phase compensation of the differential amplifier circuit 5.

The tail current source control circuit 16 generates the control signals to be supplied to the tail current source circuits 12 and 13 in response to the lower n bits D_{IN}[n-1:0] of the input digital data D_{IN}, to thereby control the tail currents Icp1, Icp2, Icn1 and Icn2 generated by the tail current source circuits 12 and 13. It is significant that the tail currents Icp1, Icp2, Icn1 and Icn2 are controlled in response to the lower n bits D_{IN}[n-1:0] of the input digital data D_{IN}. As described later in detail, in the present embodiment, the function of digital-analog conversion of n-bit resolution is achieved by controlling the tail currents Icp1, Icp2, Icn1 and Icn2 in response to the lower n bits D_{IN}[n-1:0] of the input digital data D_{IN}.

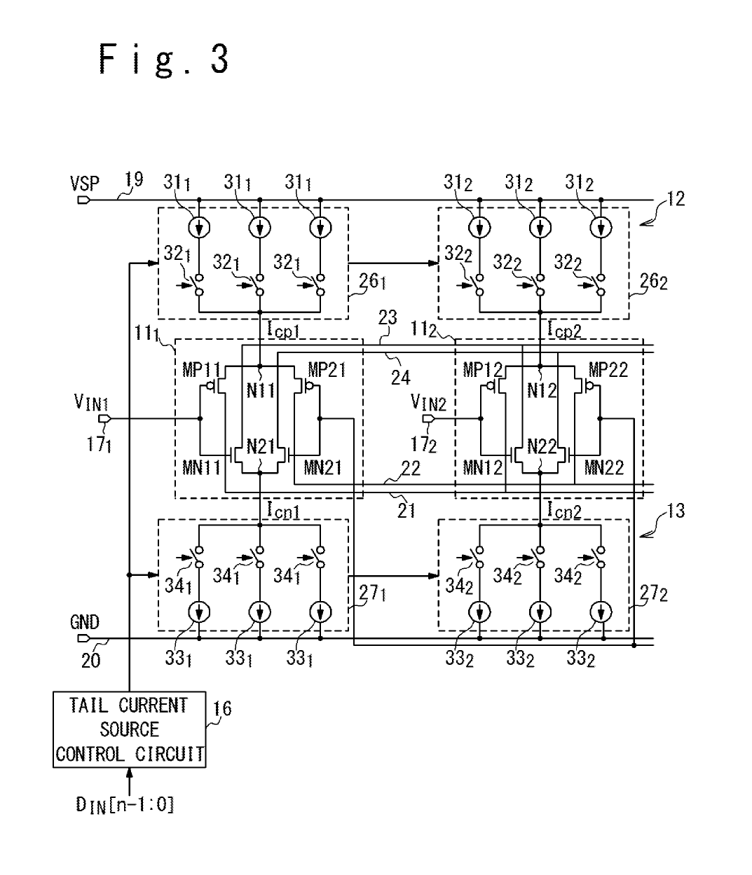

FIG. 3 is a circuit diagram illustrating one example of the configurations of the tail current source circuits 12 and 13. In this embodiment, the tail current source circuit 12 includes a variable current source 26₁ configured to supply the tail current Icp1 to the node N11 of the differential input stage 11₁; and a variable current source 26₂ configured to supply the tail current Icp2 to the node N12 of the differential input stage 11₂. The variable current source 26₁ includes: a plurality of constant current sources 31₁ connected in parallel between the positive-side line 19 and the node N11 of the differential input stage 11₁; and a plurality of switches 32₁ connected in series to the constant current sources 31₁, respectively. Similarly, the variable current source 26₂ includes: a plurality of constant current sources 31₂ connected in parallel between the positive-side line 19 and the node N12 of the differential input stage 11₂; and a plurality of switches 32₂ connected in series to the constant current sources 31₂, respectively. The turn-on-and-off of the switches 32₁ and 32₂ are controlled on the control signal received from the tail current source control circuit 16. The variable current sources 26₁ and 26₂ thus configured is able to control the current levels of the tail current Icp1 and Icp2 by adjusting the number of the switches 32₁ and 32₂ which are turned on.

In one embodiment, the constant current sources 31₁ and 31₂ may be configured to generate constant currents of the same current level. In this case, the number of the allowed current levels of the tail current Icp1 generated by the variable current source 26₁ is equal to the number of the constant current sources 31₁ and the number of the allowed current levels of the tail current Icp2 generated by the variable current source 26₂ is equal to the number of the constant current sources 31₂. In an alternative embodiment, the constant currents generated by the constant current sources 31₁ and 31₂ may have weighted current levels. This configuration effectively increases the number of the allowed current levels of the tail currents Icp1 and Icp2 output from the tail current source circuit 12. When the variable current source 26₁ includes a constant current sources 31₁ and the current levels of the constant currents generated by the constant current sources 31₁ are adjusted to I, 2×I, . . . , 2^{α-1}×I, respectively for I being a given current level, for example, the number of the allowed current levels of the tail current Icp1 generated by the variable current source 26₁ can be increased up to 2^{α}. The similar goes for the tail current Icp2 generated by the variable current source 26₂.

Similarly, the tail current source circuit 13 includes a variable current source 27₁ configured to draw the tail current Icn1 from the node N21 of the differential input stage 11₁; and a variable current source 27₂ configured to draw the tail current Icn2 from the node N22 of the differential input stage 11₂. The variable current source 27₁ includes: a plurality of constant current sources 33₁ connected in parallel between the negative-side line 20 and the node N21 of the differential input stage 11₁; and a plurality of switches 34₁ connected in series to the constant current sources 33₁, respectively. Similarly, the variable current source 27₂ includes: a plurality of constant current sources 33₂ connected in parallel between the negative-side line 20 and the node N22 of the differential input stage 11₂; and a plurality of switches 34₂ connected in series to the constant current sources 33₂, respectively. The turn-on-and-off of the switches 34₁ and 34₂ are controlled on the control signal received from the tail current source control circuit 16. The variable current sources 27₁ and 27₂ thus configured is able to control the current levels of the tail current Icn1 and Icn2 by adjusting the number of the switches 34₁ and 34₂ which are turned on.

In one embodiment, the constant current sources 33₁ and 33₂ may be configured to generate constant currents of the same current level. In this case, the number of the allowed current levels of the tail current Icn1 generated by the variable current source 27₁ is equal to the number of the constant current sources 33₁ and the number of the allowed current levels of the tail current Icn2 generated by the variable current source 27₂ is equal to the number of the constant current sources 33₂. In an alternative embodiment, the constant currents generated by the constant current sources 33₁ and 33₂ may have weighted current levels. This configuration effectively increases the number of the allowed current levels of the tail currents Icn1 and Icn2 output from the tail current source circuit 13. When the variable current source 27₁ includes a constant current sources 33₁ and the current levels of the constant currents generated by the constant current sources 33₁ are adjusted to I, 2×I, . . . , 2^{α-1}×I, respectively, for I being a given current level, the number of the allowed current levels of the tail current Icn1 generated by the variable current source 27₁ can be increased up to 2^{α}. The similar goes for the tail current Icn2 generated by the variable current source 27₂.

Next, a description is given of the operation of the semiconductor circuit 10 in this embodiment. Overall, the semiconductor circuit 10 of this embodiment is configured to output an analog output voltage V_{OUT} having a voltage level corresponding to the value of the (m+n)-bit input digital data D_{IN}. Additionally, the semiconductor circuit 10 of this embodiment achieves a low output impedance by performing impedance conversion with the differential amplifier circuit 5. This implies that the semiconductor circuit 10 of this embodiment is able to drive a load having a large capacitance. In the following, a description is given of exemplary operations of the respective circuits of the semiconductor circuit 10 in this embodiment.

The DA converter 1 selects the reference voltage V_{REFH} from the reference voltages V_{REF1} to V_{REFq} on the basis of the upper m bits of the input digital data D_{IN} and the DA converter 2 selects the reference voltage V_{REFL} from the reference voltages V_{REF1} to V_{REFq} on the basis of the upper m bits of the input digital data D_{IN}. The reference voltages V_{REFH} and V_{REFL} are selected so that the reference voltage V_{REFH} is higher than the reference voltage V_{REFL}. The DA converters 1 and 2 thus operated provide the function of m-bit digital analog conversion for the semiconductor circuit 10 of the present embodiment. The reference voltages V_{REFH} and V_{REFL} selected by the DA converters 1 and 2 are supplied to the selectors 3 and 4.

The selector 3 selects one of the reference voltages V_{REFH} and V_{REFL} in response to the lower n bits of the input digital data D_{IN} and supplies the selected reference voltage to the differential input stage 11₁ of the differential amplifier circuit 5 as the selected input voltage V_{IN1}. The selector 4 selects one of the reference voltages V_{REFH} and V_{REFL} in response to the lower n bits of the input digital data D_{IN} and supplies the selected reference voltage to the differential input stage 11₂ of the differential amplifier circuit 5 as the selected input voltage V_{IN2}. It should be noted that the selected input voltages V_{IN1} and V_{IN2} selected by the selectors 3 and 4 may be same.

When the selected input voltages V_{IN1} and V_{IN2} are same, the differential amplifier circuit 5 outputs the analog output voltage V_{OUT} so that the analog output voltage V_{OUT} has the same voltage level as the selected input voltages V_{IN1} and V_{IN2}. When the selected input voltages V_{IN1} and V_{IN2} are different, the differential amplifier circuit 5 outputs the analog output voltage V_{OUT} so that the analog output voltage V_{OUT} has a voltage level between the selected input voltages V_{IN1} and V_{IN2} in response to the lower n bits of the input digital data D_{IN}.

In detail, when the selected input voltages V_{IN1} and V_{IN2} are same, the differential amplifier circuit 5 operates as a commonly-used voltage follower and outputs the analog output voltage V_{OUT} so that the analog output voltage V_{OUT} has the same voltage level as the selected input voltages V_{IN1} and V_{IN2}, as is understood from the circuit diagram illustrated in FIG. 2.

When the selected input voltages V_{IN1} and V_{IN2} are different, on the other hand, the differential amplifier circuit 5 outputs the analog output voltage V_{OUT} depending on the current levels of the tail currents Icp1, Icp2, Icn1 and Icn2, so that the analog output voltage V_{OUT} has a voltage level between the selected input voltages V_{IN1} and V_{IN2}. When the tail current Icp1 is larger than the tail current Icp2, the analog output voltage V_{OUT} is generated to have a voltage level closer to the selected input voltage V_{IN1}. When the tail current Icp2 is larger than the tail current Icp1, the analog output voltage V_{OUT} is generated to have a voltage level closer to the selected input voltage V_{IN2}. The similar goes for the tail currents Icn1 and Icn2. When the tail current Icn1 is larger than the tail current Icn2, the analog output voltage V_{OUT} is generated to have a voltage level closer to the selected input voltage V_{IN1}. When the tail current Icn2 is larger than the tail current Icn1, the analog output voltage V_{OUT} is generated to have a voltage level closer to the selected input voltage V_{IN2}.

In the present embodiment, the tail currents Icp1, Icp2, Icn1 and Icn2 are controlled in response to the lower n bits of the input digital data D_{IN} by the tail current source control circuit 16 and therefore the number of allowed voltage levels of the analog output voltage V_{OUT} output from the differential amplifier circuit 5 is 2ⁿ for a specific combination of the selected input voltages V_{IN1} and V_{IN2}. This operation allows the semiconductor circuit 10 of the present embodiment to perform (m+n) bit digital-analog conversion as a whole.

In an alternative embodiment, one of the selected input voltages V_{IN1} and V_{IN2} may be fixed to the reference voltage V_{REFH} or V_{REFL}. Even when the selected input voltage supplied to one of the two differential input stages 11₁ and 11₂ is fixed, The selectors 3, 4 and the differential amplifier circuit 5 can achieve digital-analog conversion of the n-bit resolution by appropriately selecting the selected input voltage supplied to the other of the two differential input stages 11₁ and 11₂. When one of the selected input voltages V_{IN1} and V_{IN2} is fixed to the reference voltage V_{REFH} or V_{REFL}, the selector corresponding thereto (the selector 3 or 4) may be omitted. Such configuration is effective for circuit size reduction. It should be noted however that the configuration in which both of the selectors 3 and 4 are provided is preferable for flexibly controlling the voltage level of the analog output voltage V_{OUT} output from the semiconductor circuit 10.

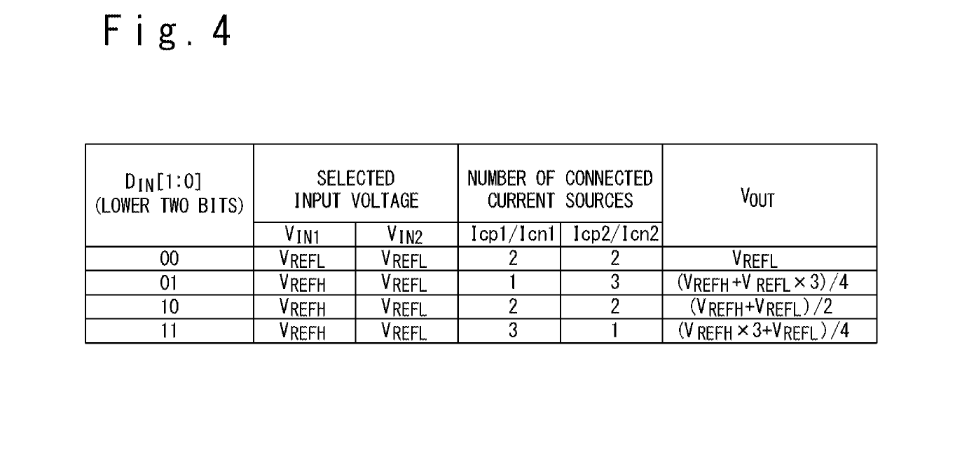

FIG. 4 is a table illustrating one example of the operation of the semiconductor circuit 10, especially the operations of the selectors 3, 4 and the differential amplifier circuit 5. Illustrated in FIG. 4 is the operation in the case when n is two. The column entitled “connected current sources” indicates the number of constant current sources used to supply the tail currents Icp1, Icn1, Icp2 and Icn2, out of the constant current sources 31₁, 31₂, 33₁ and 33₂ included in the variable current sources 26₁, 26₂, 27₁ and 27₂. In detail, the sub-column “Icp1/Icn1” of the column “connected current sources” indicates the number of the constant current sources 31₁ and 33₁ used to generate the tail currents Icp1 and Icn1, respectively, and the sub-column “Icp2/Icn2” indicates the number of the constant current sources 31₂ and 33₂ used to generate the tail currents Icp2 and Icn2, respectively.

In the present embodiment, the constant current sources 31₁ and 31₂ are adjusted to generate constant currents having the same current level and the constant current sources 33₁ and 33₂ are adjusted to generate constant currents having the same current level. In addition, the current levels of the tail currents Icp1, Icn1, Icp2 and Icn2 are controlled by controlling the number of the constant current sources 31₁, 33₁, 31₂ and 33₂ used to generate the tail currents Icp1, Icn1, Icp2 and Icn2.

The selectors 3 and 4 receives the reference voltages V_{REFH} and V_{REFL} from the DA converters 1 and 2 and selects the selected input voltages V_{IN1} and V_{IN2} in response to the lower two bits of the input digital data D_{IN}.

More specifically, when the lower two bits of the input digital data D_{IN} are “00”, the selectors 3 and 4 set both of the selected input voltages V_{IN1} and V_{IN2} to the reference voltage V_{REFL}. In this case, the analog output voltage V_{OUT} output from the differential amplifier circuit 5 is set to the reference voltage V_{REFL}. In the meantime, the tail current source control circuit 16 sets the number of the constant current sources 31₁ and 33₁ respectively used to supply the tail currents Icp1 and Icn1 to two and also sets the number of the constant current sources 31₂ and 33₂ respectively used to supply the tail currents Icp2 and Icn2 to two. In other words, the tail current source control circuit 16 turns on two of the switches 32₁, two of the switches 32₂, two of the switches 34₁ and two of the switches 34₂.

When the lower two bits of the input digital data D_{IN} are “01”, “10” or “11”, the selector 3 sets the selected input voltage V_{IN1} to the reference voltage V_{REFH} and the selector 4 sets the selected input voltage V_{IN2} to the reference voltage V_{REFL}. In the meantime, the tail current source control circuit 16 controls the current levels of the tail currents Icp1, Icn1, Icp2 and Icn2 in response to the lower two bits of the input digital data D_{IN}. In the present embodiment, the tail current source control circuit 16 controls the number of constant current sources used to supply the tail currents Icp1, Icn1, Icp2 and Icn2, by controlling the number of turned-on switches out of the switches 32₁, 34₁, 32₂ and 34₂, and thereby controls the current levels of the tail currents Icp1, Icp1, Icp2 and Icn2.

In detail, when the lower two bits of the input digital data D_{IN} are “01”, the tail current source control circuit 16 sets the number of the constant current sources 31₁ and 33₁ respectively used to supply the tail currents Icp1 and Icn1 to one and sets the number of the constant current sources 31₂ and 33₂ respectively used to supply the tail currents Icp2 and Icn2 to three. In other words, the tail current source control circuit 16 turns on one of the switches 32₁, one of the switches 34₁, three of the switches 32₂ and three of the switches 34₂. This allows adjusting the analog output voltage V_{OUT} output from the differential amplifier circuit 5 to (V_{REFH} V_{REFL}×3)/4.

When the lower two bits of the input digital data D_{IN} are “10”, the tail current source control circuit 16 sets the number of the constant current sources 31₁ and 33₁ respectively used to supply the tail currents Icp1 and Icn1 to two and sets the number of the constant current sources 31₂ and 33₂ respectively used to supply the tail currents Icp2 and Icn2 to two. In other words, the tail current source control circuit 16 turns on two of the switches 32₁, two of the switches 34₁, two of the switches 32₂ and two of the switches 34₂. This allows adjusting the analog output voltage V_{OUT} output from the differential amplifier circuit 5 to (V_{REFH} V_{REFL})/2.

When the lower two bits of the input digital data D_{IN} are “11”, the tail current source control circuit 16 sets the number of the constant current sources 31₁ and 33₁ respectively used to supply the tail currents Icp1 and Icn1 to three and sets the number of the constant current sources 31₂ and 33₂ respectively used to supply the tail currents Icp2 and Icn2 to one. In other words, the tail current source control circuit 16 turns on three of the switches 32₁, three of the switches 34₁, one of the switches 32₂ and one of the switches 34₂. This allows adjusting the analog output voltage V_{OUT} output from the differential amplifier circuit 5 to (V_{REFH}×3 V_{REFL})/4.

Through the operation procedure described above, the analog output voltage V_{OUT} is generated to have a voltage level corresponding to the lower two bits of the input digital data D_{IN} from the reference voltages V_{REFH} and V_{REFL}, which are selected in response to the upper m bits of the input digital data D_{IN}, in the operation of the semiconductor circuit 10 illustrated in FIG. 4. Accordingly, the semiconductor circuit 10 performs digital-analog conversion of (m+2)-bit resolution as a whole.

It should be noted that the selector 4 is not necessary when the operation illustrated in FIG. 4 is performed, because the selected input voltage V_{IN2} supplied to the differential input stage 11₂ from the selector 4 is fixed to the reference voltage V_{REFL}. In this case, the reference voltage V_{REFL} output from the DA converter 2 may be directly supplied to the differential amplifier circuit 5 as the selected input voltage V_{IN2}.

It should be noted here that the semiconductor circuit 10 of this embodiment achieves the (m+n)-bit resolution although the number q of the reference voltages V_{REF1} to V_{REFq} supplied thereto is 2^{m}+1. A DA converter configured to simply select an analog output voltage from a plurality of reference voltages requires 2^{(m+n)} different reference voltages for achieving the (m+n)-bit resolution. The configuration of the semiconductor circuit 10 of the present embodiment, which provides (m+n)-bit resolution, allows reducing the number q of the reference voltages V_{REF1} to V_{REFq} to be supplied to the semiconductor circuit 10 down to 2^{m}+1. This effectively reduces the circuit size. As thus discussed, the semiconductor circuit 10 of this embodiment achieves a higher resolution and a reduced circuit size at the same time, in performing digital-analog conversion and impedance conversion.

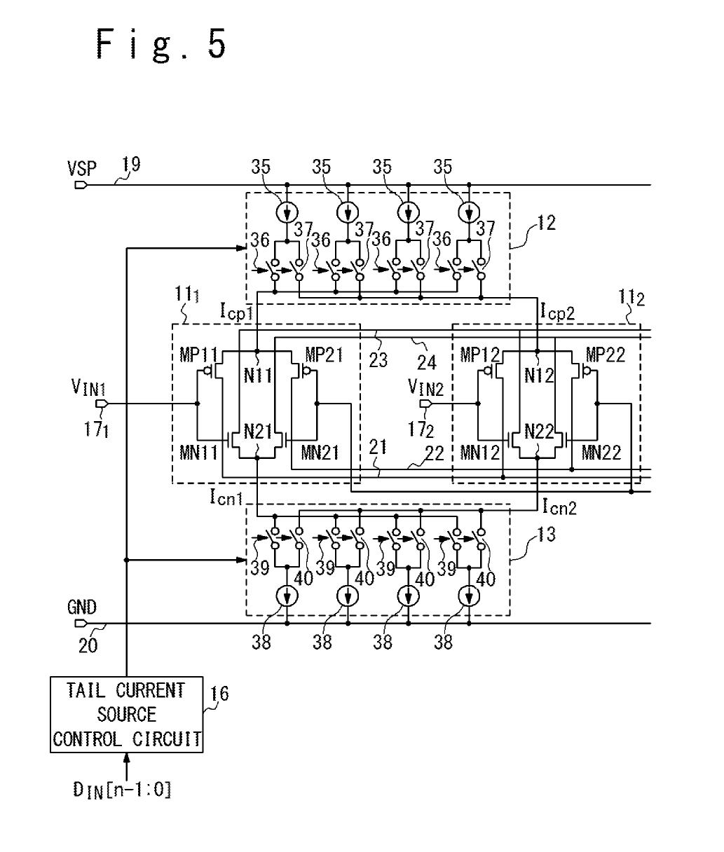

In the following, various modifications of the semiconductor circuit 10 of the present embodiment are described. FIG. 5 is a circuit diagram illustrating the configurations of the tail current source circuits 12 and 13 of the differential amplifier circuit 5 in one modification of the semiconductor circuit 10 of the present embodiment.

In the modification illustrated in FIG. 5, the tail current source circuit 12 includes a plurality of constant current sources 35, a plurality of switches 36 and a plurality of switches 37. One switch 36 and one switch 37 are associated with one constant current source 35. The constant current sources 35 are connected to the positive-side line 19 in parallel, and each configured to generate a constant current. Each switch 36 is connected between the corresponding constant current source 35 and the node N11 of the differential input stage 11₁ and each switch 37 is connected between the corresponding constant current source 35 and the node N12 of the differential input stage 11₂. The switches 36 and 37 form a switch circuit configured to connect each of the constant current sources 35 to any one of the node N11 of the differential input stage 11₁ and the node N12 of the differential input stage 11₂, in response to the lower n bits of the input digital data D_{IN} under the control of the tail current source control circuit 16. In other words, the switches 36 and 37 connected to each constant current source 35 have the function of electrically connecting each constant current source 35 to any one of the node N11 of the differential input stage 11₁ and the node N12 of the differential input stage 11₂.

The tail current source circuit 13 is configured similarly to the tail current source circuit 12; the tail current source circuit 13 includes a plurality of constant current sources 38, a plurality of switches 39 and a plurality of switches 40. One switch 39 and one switch 40 are associated with each constant current source 38. The constant current sources 38 are connected to the negative-side line 20 in parallel, and each configured to generate a constant current. Each switch 39 is connected between the corresponding constant current source 38 and the node N21 of the differential input stage 11₁ and each switch 40 is connected between the corresponding constant current source 38 and the node N22 of the differential input stage 11₂. The switches 39 and 40 form a switch circuit configured to connect each of the constant current sources 38 to any one of the node N21 of the differential input stage 11₁ and the node N22 of the differential input stage 11₂, in response to the lower n bits of the input digital data D_{IN} under the control of the tail current source control circuit 16. The switches 39 and 40 connected to each constant current source 38 have the function of electrically connecting each constant current source 38 to any one of the node N21 of the differential input stage 11₁ and the node N22 of the differential input stage 11₂.

The configuration illustrated in FIG. 5 allows using each constant current source 35 included in the tail current source circuit 12 both for generating the tail current Icp1 in the differential input stage 11₁ and for generating the tail current Icp2 in the differential input stage 11₂, in accordance with the necessity. This allows effective use of each constant current source 35 and thereby reduces the circuit size of the tail current source circuit 12.

The configuration of the tail current source circuit 12 illustrated in FIG. 5 is especially useful when the tail currents Icp1 and Icp2 are variably controlled while the sum of the number of constant current sources used for generating the tail current Icp1 and that for generating the tail current Icp2 is fixed. Discussed below is the operation illustrated in FIG. 4 is performed in the case when the number of constant current sources 35 is four and the current levels of the constant currents generated by the constant current sources 35 are same. When the lower two bits of the input digital data D_{IN} is “00”, the numbers of the constant current sources used for generating the tail currents Icp1 and Icp2 are both two; in this case, two of the constant current sources 35 are connected to the node N11 of the differential input stage 11₁ and the other two of the constant current sources 35 are connected to the node N12 of the differential input stage 11₂. Similarly, when the lower two bits of the input digital data D_{IN} is “01”, the numbers of the constant current sources used for generating the tail currents Icp1 and Icp2 are one and three, respectively; in this case, one of the constant current sources 35 is connected to the node N11 of the differential input stage 11₁ and the remaining three of the constant current sources 35 are connected to the node N12 of the differential input stage 11₂. In both cases, all of the four constant current sources 35 are used for generating the tail currents Icp1 and Icp2. Also when the lower two bits of the input digital data D_{IN} is “01” or “11”, all of the four constant current sources 35 are used for generating the tail currents Icp1 and Icp2. As thus discussed, the configuration illustrated in FIG. 5, in which each constant current source 35 can be selectively connected to any of the node N11 of the differential input stage 11₁ and the node N12 of the differential input stage 11₂, allows efficient use of the constant current sources 35.

The same discussion applies to the tail current source circuit 13. The configuration illustrated in FIG. 5 allows using each constant current source 38 included in the tail current source circuit 13 both for generating the tail current Icn1 in the differential input stage 11₁ and for generating the tail current Icn2 in the differential input stage 11₂, in accordance with the necessity. This configuration allows efficient use of each constant current source 38 and thereby reduces the circuit size of the tail current source circuit 13. The configuration of the tail current source circuit 13 illustrated in FIG. 5 is especially useful in the case when the tail currents Icn1 and Icn2 are variably controlled while the sum of the number of constant current sources used for generating the tail current Icn1 and that for generating the tail current Icn2 is fixed.

Although FIG. 3 illustrates the configuration of the differential amplifier circuit 5 in which the differential input stages 11₁ and 11₂ each include both of a PMOS differential pair and an NMOS differential pair, the differential input stages 11₁ and 11₂ may each include only a PMOS differential pair in an alternative embodiment. Such configuration effectively reduces the number of circuit elements included in the differential input stages 11₁ and 11₂.

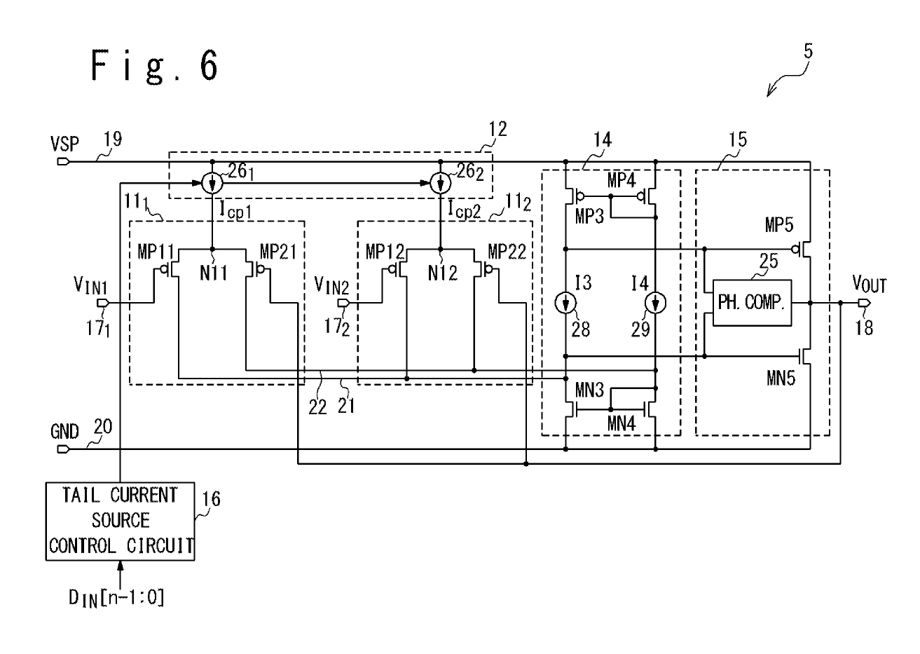

FIG. 6 is a circuit diagram illustrating the configuration of the differential amplifier circuit 5 when the differential input stages 11₁ and 11₂ each include only a PMOS differential pair. In the configuration of the differential amplifier circuit 5 illustrated in FIG. 6, the NMOS transistors MN11, MN21, MN12 and MN22, which constitute NMOS transistor pairs, are removed from the differential input stages 11₁ and 11₂. In connection with the removal of the NMOS transistor pairs, the tail current source circuit 13, which supplies the tail currents Icn1 and Icn2 to the NMOS differential pairs of the differential input stages 11₁ and 11₂, and the drain interconnections 23 and 24 connected to the NMOS transistors MN11, MN21, MN12 and MN22 are also removed.

In another alternative embodiment, the differential input stages 11₁ and 11₂ may each include only an NMOS differential pair. Such configuration also reduces the circuit elements included in the differential input stages 11₁ and 11₂.

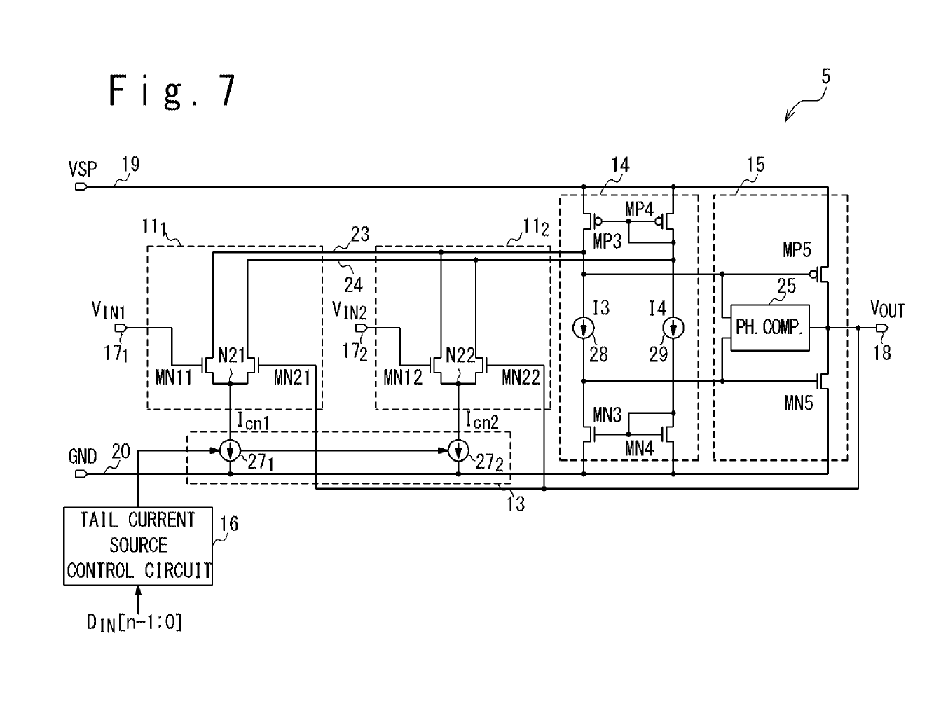

FIG. 7 is a circuit diagram illustrating the configuration of the differential amplifier circuit 5 when the differential input stages 11₁ and 11₂ each include only an NMOS differential pair. In the configuration of the differential amplifier circuit 5 illustrated in FIG. 7, the PMOS transistors MP11, MP21, MP12 and MP22, which constitute PMOS transistor pairs, are removed from the differential input stages 11₁ and 11₂. In connection with the removal of the PMOS transistor pairs, the tail current source circuit 12, which supplies the tail currents Icp1 and Icp2 to the PMOS differential pairs of the differential input stages 11₁ and 11₂, and the drain interconnections 21 and 22 connected to the PMOS transistors MP11, MP21, MP12 and MP22 are also removed.

Although FIG. 3 illustrates the configuration in which the differential amplifier circuit 5 includes two differential input stages (11₁ and 11₂), the differential amplifier circuit 5 may include three or more differential input stages. Especially, when the differential amplifier circuit 5 includes 2^{b} differential input stages for b being an integer of two or more, such configuration can provide b-bit resolution for the differential amplifier circuit 5 in combination with the operation of selectors which supply selected input voltages to the respective differential input stages. This is advantageous for increasing the resolution.

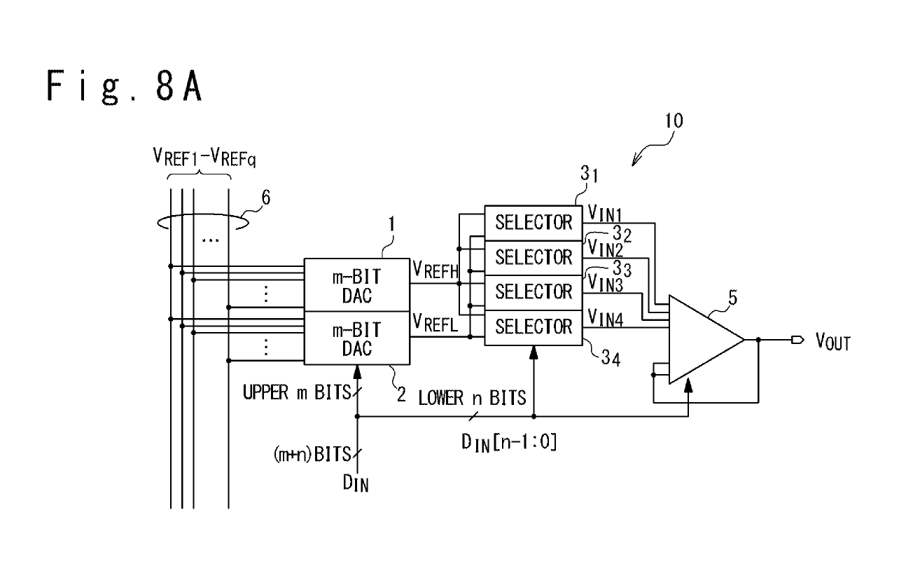

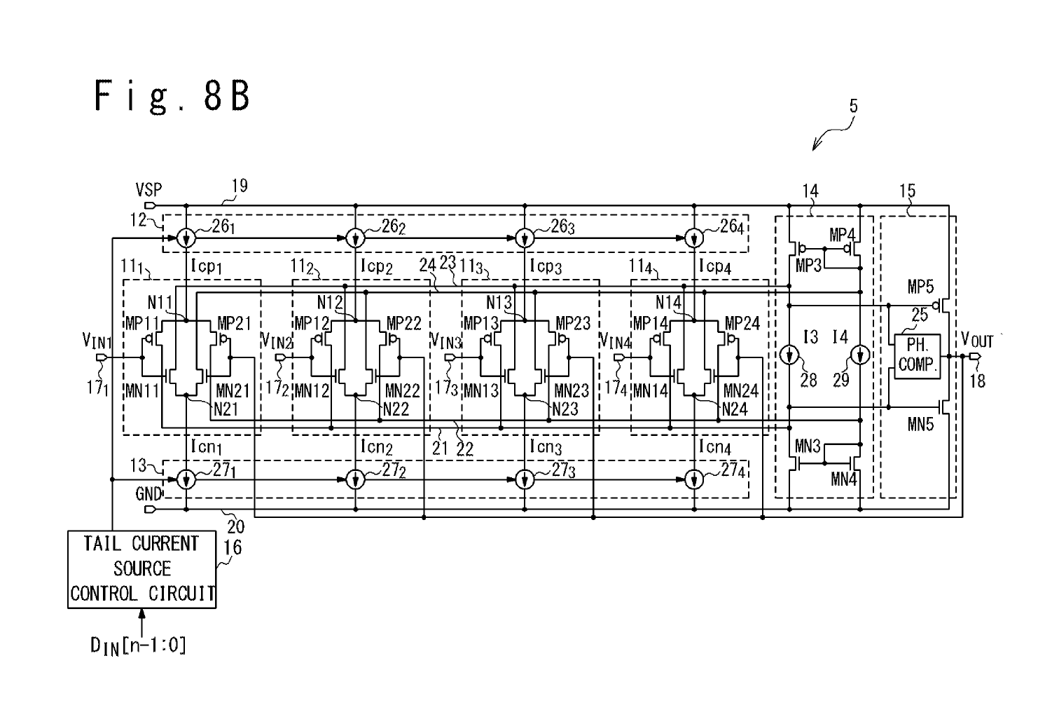

FIG. 8A is a circuit diagram illustrating the configuration of the semiconductor circuit 10 in another alternative embodiment; more specifically, FIG. 8 illustrates the configuration of the semiconductor circuit 10 when the differential amplifier circuit 5 includes four differential input stages. The configuration of the semiconductor circuit 10 illustrated in FIG. 8A is almost similar to that illustrated in FIG. 1; the difference is that four selectors 3₁ to 3₄, the number of which is same as that of the differential input stages, are included in the configuration of the semiconductor circuit 10 illustrated in FIG. 8A. The reference voltages V_{REFH} and V_{REFL} which are selected in response to the upper m bits of the input digital data are supplied to each of the selectors 3₁ to 3₄ from the DA converters 1 and 2. The selectors 3₁ to 3₄ respectively select the selected input voltages V_{IN1} to V_{IN4} to be supplied to the differential amplifier circuit 5 from the reference voltages V_{REFH} and V_{REFL} in response to the lower n bits of the input digital data D_{IN}. The selected input voltages V_{IN1} to V_{IN4} are supplied to the differential amplifier circuit 5 from the selectors 3₁ to 3₄, respectively.

FIG. 8B is a circuit diagram illustrating one example of the configuration of a differential amplifier circuit 5 including four differential input stages. In FIG. 8B, the four differential input stages are denoted by the numerals 11₁ to 11₄. The configuration of the differential amplifier circuit 5 illustrated in FIG. 8B is similar to that illustrated in FIG. 2. The differential amplifier circuit 5 illustrated in FIG. 8B includes tail current sources 12, 13, an active load circuit 14, an output stage 15 and a tail current source control circuit 16, in addition to the differential input stages 11₁ to 11₄.

Each differential input stages 11; includes PMOS transistors MP1i, MP2i, and NMOS transistors MN1i and MN2i, where i is any integer from one to four.

The PMOS transistors MP1i and MP2i have commonly-connected sources and form a PMOS differential pair. The sources of the PMOS transistors MP1i and MP2i are commonly connected to the node N1i. The drain of the PMOS transistor MP1i is connected to the drain interconnection 21 and the drain of the PMOS transistor MP2i is connected to the drain interconnection 22.

The NMOS transistors MN1i and MN2i have commonly-connected sources and form an NMOS differential pair. The sources of the NMOS transistors MN1i and MN2i are commonly connected to the node N2i. The drain of the NMOS transistor MN1i is connected to the drain interconnection 23 and the drain of the NMOS transistor MN2i is connected to the drain interconnection 24.

The gate of the PMOS transistor MP1i of each differential input stage 11ᵢ is connected to the input node 17ᵢ to which the selected input voltage V_{INi} is supplied from the selector 3ᵢ and the gate of the PMOS transistor MP2i of each differential input stage 11ᵢ is connected to the output node 18 from which the analog output voltage V_{OUT} is output. Similarly, the gate of the NMOS transistor MN1i of each differential input stage 11ᵢ is connected to the input node 17ᵢ and the gate of the NMOS transistor MN2i of each differential input stage 11ᵢ is connected to the output node 18.

The tail current source circuit 12 includes four variable current sources 26₁ to 26₄, the number of which is equal to that of the differential input stages. Each variable current source 26ᵢ supplies a tail current Icpi to the node N1i of the corresponding differential input stage 11ᵢ. The current levels of the tail currents Icp1 to Icp4 are controlled on the lower n bits of the input digital data D_{IN}.

Similarly, the tail current source circuit 13 includes four variable current sources 27₁ to 27₄, the number of which is equal to that of the differential input stages. Each variable current source 27; draws a tail current Icni from the node N2i of the corresponding differential input stage 11ᵢ. The current levels of the tail currents Icn1 to Icn4 are controlled on the lower n bits of the input digital data D_{IN}.

The semiconductor circuit 10 configured as illustrated in FIGS. 8A and 8B can provide an additional resolution of two bits through the configuration of the differential amplifier circuit 5, which includes four differential input stages 11₁ to 11₄, and the operation of the selectors 3₁ to 3₄. Accordingly, the configuration illustrated in FIGS. 8A and 8B allows increasing the resolution of the digital-analog conversion provided by the semiconductor circuit 10 and/or reducing the required number of the current levels of the tail currents supplied by each of the variable current sources 26ᵢ and 27ᵢ. It should be noted however that the increase in the number of the differential input stages in the configuration of the semiconductor circuit 10 illustrated in FIGS. 8A and 8B undesirably increases the total current level of the tail currents to be supplied to the differential input stages, causing an undesired increase in the consumed current. In view of the reduction in the consumed current, it is preferable that the number of the differential input stages is two, as illustrated in FIGS. 1 and 2.

It should be noted that, also when the differential amplifier circuit 5 includes three or more differential input stages, the tail current source circuit 12 may be configured so that each of the constant current sources 35 included in the tail current source circuit 12 can be used for generating the tail currents in any of the three or more differential input stages, as is the case with the configuration illustrated in FIG. 5. Similarly, the tail current source circuit 13 may be configured so that each of the constant current sources 38 included in the tail current source circuit 13 can be used for generating the tail currents in any of the three or more differential input stages.

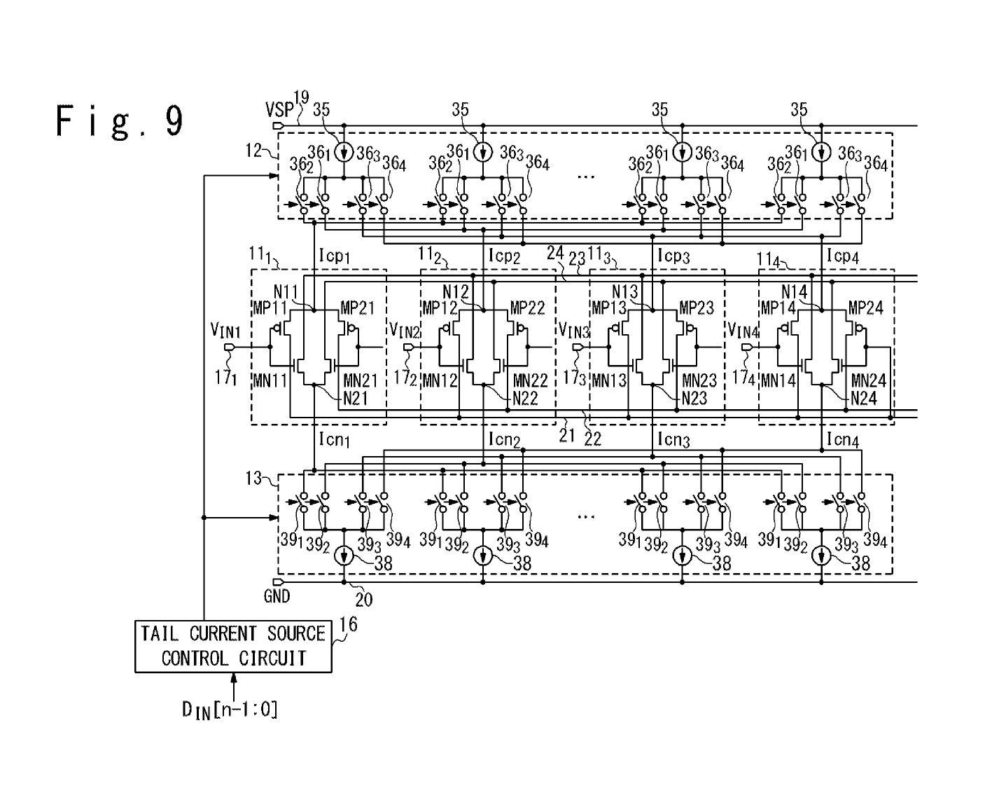

FIG. 9 is a circuit diagram illustrating one example of the configurations of the tail current source circuits 12 and 13 when the differential amplifier circuit 5 includes four differential input stages 11₁ to 11₄. In the configuration illustrated in FIG. 9, the tail current source circuit 12 includes a plurality of constant current sources 35, and a plurality of switches 36₁ to 36₄. Although four constant current sources 35 are illustrated in FIG. 9, a person skilled in the art would appreciate that a sufficient number of constant current sources 35 are provided for adjusting the current levels of the tail currents Icp1 to Icp4, in an actual implementation. One switch 36₁, one switch 36₂, one switch 36₃ and one switch 36₄ are associated with each constant current source 35. The constant current sources 35 are connected to the positive-side line 19 in parallel and each configured to generate a constant current. Each switch 36₁ is connected between the corresponding constant current source 35 and the node N11 of the differential input stage 11₁, and each switch 36₂ is connected between the corresponding constant current source 35 and the node N12 of the differential input stage 11₂. Each switch 36₃ is connected between the corresponding constant current source 35 and the node N13 of the differential input stage 11₃, and each switch 36₄ is connected between the corresponding constant current source 35 and the node N14 of the differential input stage 11₄. The switches 36₁ to 36₄ form a switch circuit which is configured to connect each of the constant current sources 35 to a selected one of the nodes N11 to N14 of the differential input stages 11₁ to 11₄ in response to the lower n bits of the input digital data D_{IN} under the control of the tail current source control circuit 16.

The tail current source circuit 13 is configured similarly to the tail current source circuit 12; the tail current source circuit 13 includes a plurality of constant current sources 38, and a plurality of switches 39₁ to 39₄. Although four constant current sources 38 are illustrated in FIG. 9, a person skilled in the art would appreciate that a sufficient number of constant current sources 38 are provided for adjusting the current levels of the tail currents Icn1 to Icn4, in an actual implementation. One switch 39₁, one switch 39₂, one switch 39₃ and one switch 39₄ are associated with each constant current source 38. The constant current sources 38 are connected to the negative-side line 20 in parallel and each configured to generate a constant current. Each switch 39₁ is connected between the corresponding constant current source 38 and the node N21 of the differential input stage 11₁, and each switch 39₂ is connected between the corresponding constant current source 38 and the node N22 of the differential input stage 11₂. Each switch 39₃ is connected between the corresponding constant current source 38 and the node N23 of the differential input stage 11₃, and each switch 39₄ is connected between the corresponding constant current source 38 and the node N24 of the differential input stage 11₄. The switches 39₁ to 39₄ form a switch circuit which is configured to connect each of the constant current sources 38 to a selected one of the nodes N21 to N24 of the differential input stages 11₁ to 11₄ in response to the lower n bits of the input digital data D_{IN} under the control of the tail current source control circuit 16.

The configuration illustrated in FIG. 9 allows using each constant current source 35 included in the tail current source circuit 12 for generating any of the tail currents Icp1 to Icp4 in the differential input stage 11₁ to 11₄, in accordance with the necessity. This configuration allows efficient use of each constant current source 35 and thereby reduces the circuit size of the tail current source circuit 12. The similar goes for the tail current source circuit 13. The configuration illustrated in FIG. 9 allows using each constant current source 38 included in the tail current source circuit 13 for generating any of the tail currents Icn1 to Icn4 in the differential input stage 11₁ to 11₄, in accordance with the necessity. This configuration allows efficient use of each constant current source 38 and thereby reduces the circuit size of the tail current source circuit 13.

It should be noted that, also in the circuit configuration illustrated in FIG. 9, one of the selected input voltages V_{IN1} to V_{IN4} supplied to the differential input stages 11₁ to 11₄ may be fixed to the reference voltage V_{REFH} or V_{REFL}. In this case, the selector outputting the fixed one of the selected input voltage may be removed. In general, the selected input voltage supplied to one of the N differential input stages included in the differential amplifier circuit 5 may be fixed to the reference voltage V_{REFH} or V_{REFL}, for N being an integer of two or more; in this case, (N−1) selectors are provided for the semiconductor circuit 10. It should be noted however that the configuration in which N selectors are provided to supply the selected input voltages to N differential input stages, respectively (for example, the configuration in which the selectors 3₁ to 3₄ are provided to supply the selected input voltages V_{IN1} to V_{1N4} to the differential input stages 11₁ to 11₄ as illustrated in FIG. 9) is preferable for flexibly controlling the voltage level of the analog output voltage V_{OUT} output from the semiconductor circuit 10.

Also when the differential amplifier circuit 5 includes three or more differential input stages, each of the differential input stages may include only one of a PMOS differential pair and an NMOS differential pair. For example, all of the differential input stages may include only a PMOS differential pair or include only an NMOS differential pair. The configuration in which the differential input stages each include only one of a PMOS differential pair and an NMOS differential pair effectively reduces the number of circuit elements included in each of the differential input stages.

It should be noted however that, for enlarging the operable voltage range of the differential amplifier circuit 5, it is preferable that at least one of the differential input stages include a PMOS differential pair and at least another one of the differential input stages include an NMOS differential pair, when each of the differential input stages includes only one of a PMOS differential pair and an NMOS differential pair. For maintaining the circuit symmetry and enlarging the operable voltage range, it is preferable that the number of the differential input stages is even and a half of the differential input stages include only a PMOS differential pair and the remaining half of the differential input stages include only an NMOS differential pair.

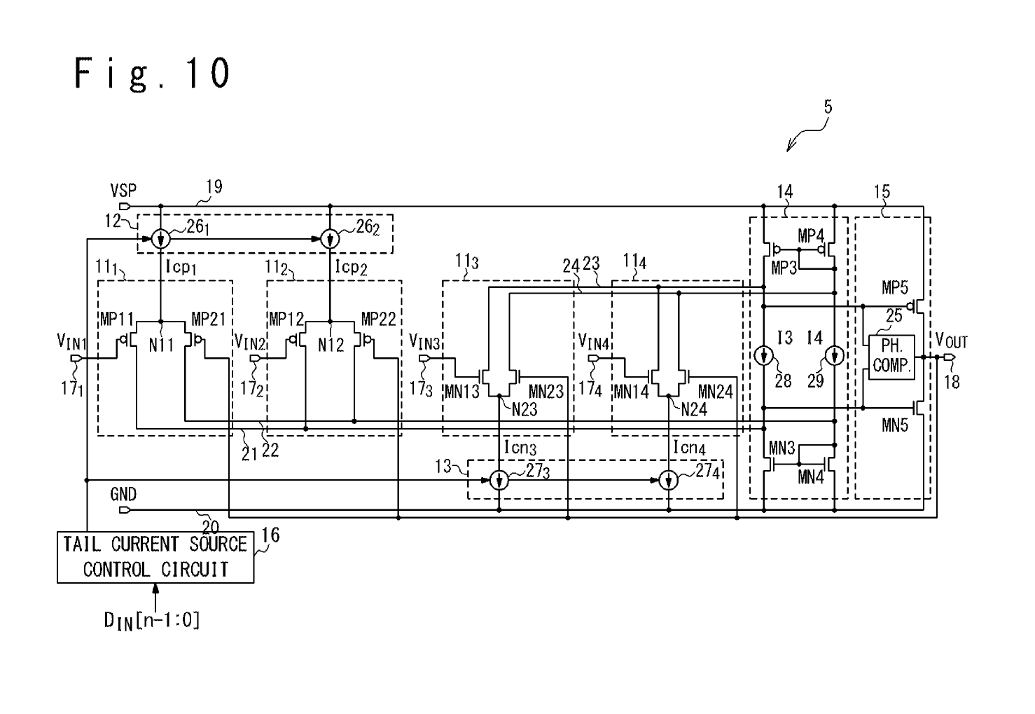

FIG. 10 is a circuit diagram illustrating an example of the configuration of the differential amplifier circuit 5 when the differential amplifier circuit 5 includes four differential input stages 11₁ to 11₄, where two differential input stages 11₁ and 11₂ each include only a PMOS differential pair and the other two differential input stages 11₃ and 11₄ each include only an NMOS differential pair.

The differential input stage 11₁ includes PMOS transistors MP11 and MP21, and the differential input stage 11₂ includes PMOS transistors MP12 and MP22. The PMOS transistors MP11 and MP21 of the differential input stage 11₁ have sources commonly connected to the node N11 and the PMOS transistors MP12 and MP22 of the differential input stage 11₂ have sources commonly connected to the node N12. The drains of the PMOS transistor MP11 of the differential input stage 11₁ and the PMOS transistor MP12 of the differential input stage 11₂ are connected to the drain interconnection 21 and the drains of the PMOS transistor MP21 of the differential input stage 11₁ and the PMOS transistor MP22 of the differential input stage 11₂ are connected to the drain interconnection 22.

The differential input stage 11₃ includes NMOS transistors MN13 and MP23, and the differential input stage 11₄ includes NMOS transistors MN14 and MP24. The NMOS transistors MN13 and MN23 of the differential input stage 11₃ have sources commonly connected to the node N13 and the NMOS transistors MN14 and MN24 of the differential input stage 11₄ have sources commonly connected to the node N14. The drains of the NMOS transistor MN13 of the differential input stage 11₃ and the NMOS transistor MN14 of the differential input stage 11₄ are connected to the drain interconnection 23 and the drains of the NMOS transistor MN23 of the differential input stage 11₃ and the NMOS transistor MN24 of the differential input stage 11₄ are connected to the drain interconnection 24.

The gate of the PMOS transistor MP11 of the differential input stage 11₁ is connected to the input node 17₁ to which the selected input voltage V_{IN1} is supplied from the selector 3₁ and the gate of the PMOS transistor MP12 of the differential input stage 11₂ is connected to the input node 17₂ to which the selected input voltage V_{IN2} is supplied from the selector 3₂. The gates of the PMOS transistor MP21 of the differential input stage 11₁ and the PMOS transistor MP22 of the differential input stage 11₂ are connected to the output node 18 from which the analog output voltage V_{OUT} is output.

Similarly, the gate of the NMOS transistor MN13 of the differential input stage 11₃ is connected to the input node 17₃ to which the selected input voltage V_{IN3} is supplied from the selector 3₃ and the gate of the NMOS transistor MN14 of the differential input stage 11₄ is connected to the input node 17₄ to which the selected input voltage V_{IN4} is supplied from the selector 3₄. The gates of the NMOS transistor MN23 of the differential input stage 11₃ and the NMOS transistor MN24 of the differential input stage 11₄ are connected to the output node 18.

The tail current source circuit 12 includes a variable current source 26₁ which supplies a tail current Icp1 to the node N11 of the differential input stage 11₁ and a variable current source 26₂ which supplies a tail current Icp2 to the node N12 of the differential input stage 11₂. The current levels of the tail currents Icp1 and Icp2 are controlled on the lower n bits of the input digital data D_{IN}.

The tail current source circuit 13 includes a variable current source 27₃ which supplies a tail current Icn3 to the node N23 of the differential input stage 11₃ and a variable current source 27₄ which supplies a tail current Icn4 to the node N24 of the differential input stage 11₄. The current levels of the tail currents Icn3 and Icn4 are controlled on the lower n bits of the input digital data D_{IN}.

The configuration of the differential amplifier circuit 5 illustrated in FIG. 10 offers a resolution of two bits through the configuration in which the differential amplifier circuit 5 includes four differential input stages 11₁ to 11₄ and the operation of the selectors 3₁ to 3₄. Accordingly, the configuration illustrated in FIG. 10 allows increasing the resolution of the digital-analog conversion offered by the semiconductor circuit 10 and/or reducing the required number of current levels of the tail currents supplied by the variable current sources 26ᵢ and 27ᵢ. Additionally, the configuration illustrated in FIG. 10 allows reducing the number of circuit elements included in each differential input stage. This effectively reduces the circuit size.

Next, a description is given of preferred applications of the semiconductor circuit 10 of the present embodiment described above. The semiconductor circuit 10 of the present embodiment, which has the function of digital-analog conversion and impedance conversion, is preferably used in a display driver which drives the source lines of a display panel (e.g., a liquid crystal display panel and an OLED (organic light emitting diode) display panel) in a panel display device.

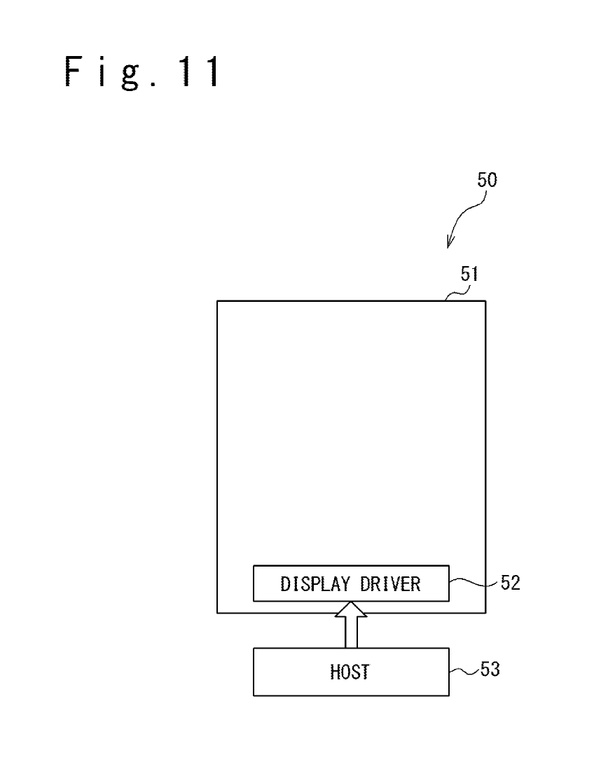

FIG. 11 is a block diagram schematically illustrating the configuration of a panel display device (denoted by the numeral 50 in FIG. 11) in one embodiment. The panel display device 50 includes a display panel 51 and a display driver 52. The display panel 51 includes gate lines, source lines and pixels arrayed in rows and columns (note that the gate lines, source lines and pixels are not shown in FIG. 11). Each pixel includes three subpixels displaying different colors (typically, red, green and blue) and each subpixel includes a pixel circuit. When the display panel 51 is an OLED display panel, in one embodiment, each subpixel includes a select transistor, a drive transistor, a hold capacitor and an OLED element. When the display panel 51 is a liquid crystal display panel, each subpixel includes a select transistor, a hold capacitor and a pixel electrode. The color displayed by each pixel depends on the respective brightness levels of the three subpixels.

The display driver 52 drives the source lines of the display panel 51 in response to image data and control data received from a host 53.

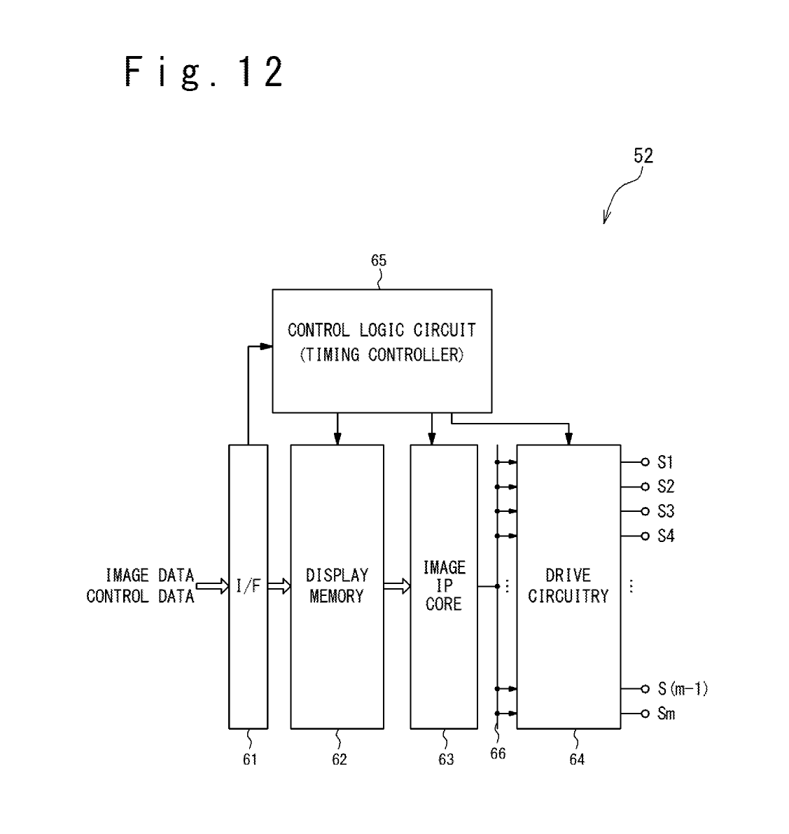

FIG. 12 is a block diagram schematically illustrating the configuration of the display driver 52. The display driver 52 includes an interface 61, a display memory 62, an image IP core 63, a drive circuitry 64 and a control logic circuit 65.

The interface 61 communicates with the host 53 to exchange various data required for operating the display driver 52. More specifically, the interface 61 receives image data from the host 53 and forwards the received image data to the display memory 62. Additionally, the interface 61 receives control data from the host 53 and supplies control commands and control parameters to the control logic circuit 65 in response to the contents of the received control data.

The display memory 62 temporarily stores the image data received from the interface 61 and forwards the image data to the image IP core 63. The image IP core 63 performs desired image processing on the image data received from the display memory 62 and outputs image data obtained through the image processing to the drive circuitry 64.

The drive circuitry 64 is connected to the image IP core 63 via a data bus 66 and drives the source lines of the display panel 51 connected to source outputs S1 to Sx in response to the image data received from the image IP core 63, where x is an integer of two or more. The configuration of the drive circuitry 64 will be described later in detail.

The control logic circuit 65 controls the respective circuits of the display driver 52 in response to the control commands and control parameters received from the interface 61. The control logic circuit 65 also operates as a timing controller which generates timing control signals (including a vertical sync signal and a horizontal sync signal) used for timing control of the respective circuits of the display driver 52.

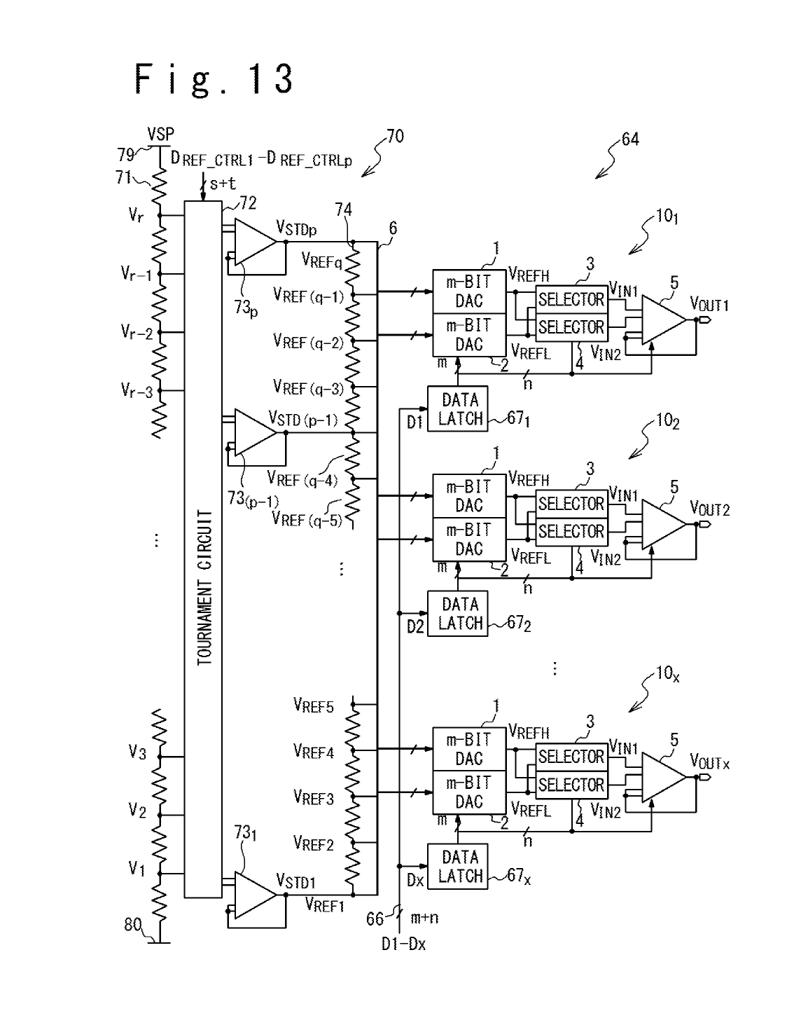

FIG. 13 is a circuit diagram illustrating one example of the configuration of the drive circuitry 64. The drive circuitry 64 includes x semiconductor circuits 10 configured as described above, a reference voltage bus 6 and data latches 67₁ to 67ₓ, where x is an integer of two or more. In FIG. 13, suffixes are attached with the numerals “10” to distinguish the x semiconductor circuits 10 from one another. In the drive circuitry 64 configured as illustrated in FIG. 13, the semiconductor circuits 10₁ to 10ₓ are used to output source voltages to the source outputs S1 to Sx. The source voltages output to the source outputs S1 to Sx are supplied to the source lines of the display panel 51 which are connected to the source outputs S1 to Sx, to drive the source lines.

The data latches 67₁ to 67ₓ receive image data D1 to Dx corresponding to the source outputs S1 to Sx from the image IP core 63 via the data bus 66. The image data D1 to Dx are (m+n)-bit data. The data latches 67₁ to 67ₓ supplies the image data D1 to Dx to the semiconductor circuits 10₁ to 10ₓ.

The semiconductor circuits 10₁ to 10ₓ perform digital-analog conversion on the image data D1 to Dx received from the data latches 67₁ to 67ₓ, respectively, to output the analog output voltages V_{OUT1} to V_{OUTx} from the outputs of the differential amplifier circuits 5. The reference voltages V_{REF1} to V_{REFq} (where q=2^{m}+1) supplied to the semiconductor circuits 10₁ to 10ₓ from the reference voltage bus 6 are used for this digital analog conversion. The analog output voltages V_{OUT1} to V_{OUTx} output from the semiconductor circuits 10₁ to 10ₓ are supplied to the source outputs S1 to Sx and used as the source voltages to drive the source lines.

Although not illustrated in FIG. 13, a precharge circuit which precharges the source lines and a switch circuit which switches connections between the semiconductor circuits 10₁ to 10ₓ and the source outputs S1 to Sx may be disposed between the semiconductor circuits 10₁ to 10ₓ and the source outputs S1 to Sx.

In the configuration illustrated in FIG. 13, the reference voltages V_{REF1} to V_{REFq}, which are supplied to the drive circuitry 64, are generated by a gamma circuit (reference voltage generator circuit) 70. In one embodiment, the gamma circuit 70 includes a resistor string 71, a tournament circuit 72, preamplifiers 73₁ to 73ₚ and a resistor string 74.

The resistor string 71 is connected between a positive-side line 79 and a negative-side line 80 and used to generate voltages V₁ to Vᵣ at respective positions thereof through voltage dividing. In the present embodiment, an analog power supply voltage VSP is supplied to the positive-side line 79 and a negative-side line 80 is connected to the circuit ground.

The tournament circuit 72 receives the voltages V₁ to Vᵣ from the resistor string 71 and supplies selected ones of the voltages V₁ to Vᵣ to the preamplifiers 73₁ to 73ₚ, respectively. The voltages supplied to the preamplifiers 73₁ to 73ₚ are controlled in response to reference voltage control data D_{REF}_{_}_{CTRL1} to D_{REF}_{_}_{CTRLp}, respectively. The reference voltage control data D_{REF}_{_}_{CTRL1} to D_{REF}_{_}_{CTRLp} are each (s+t)-bit digital data used to control the voltage levels of the reference voltages V_{REF1} to V_{REFq}. The reference voltage control data D_{REF}_{_}_{CTRL1} to D_{REF}_{_}_{CTRLp} are associated with the preamplifiers 73₁ to 73ₚ, respectively, and the voltages supplied from the tournament circuit 72 to the preamplifiers 73₁ to 73ₚ are selected in response to the reference voltage control data D_{REF}_{_}_{CTRL1} to D_{REF}_{_}_{CTRLp}.

The preamplifiers 73₁ to 73ₚ respectively generates the standard voltages V_{STD1} to V_{STDp} from the voltages received from the tournament circuit 72 and supply the standard voltages V_{STD1} to V_{STDp} to the resistor string 74. The standard voltages V_{STD1} to V_{STDp} are generated so as to satisfy the following requirement (1):

V_{STD1}<V_{STD2}< . . . <V_{STD(p-1)}<V_{STDp}. (1)

The resistor string 74 receives the standard voltages V_{STD1} to V_{STDp} from the preamplifiers 73₁ to 73ₚ and generates the reference voltages V_{REF1} to V_{REFq} through voltage dividing. In detail, the standard voltage V_{STD1} is supplied to one end of the resistor string 74 and the standard voltage V_{STDp} is supplied to the other end of the resistor string 74. The reference voltages VSTD₂ to V_{STD(p-1)} are supplied to intermedium positions of the resistor string 74. The reference voltages V_{REF1} to V_{REFq} are generated at predefined positions of the resistor string 74 and the reference voltages V_{REF1} to V_{REFq} thus generated are supplied to the DA converters 1 and 2 of each of the semiconductor circuits 10₁ to 10ₓ via the reference voltage bus 6. The display driver 52 of the present embodiment, which is configured as illustrated in FIG. 13, can adjust the voltage levels of the reference voltages V_{REF1} to V_{REFq} through appropriately adjusting the voltage levels of the reference voltages V_{STD1} to V_{STDp} and thereby adjust the gamma characteristics of the display driver 52.

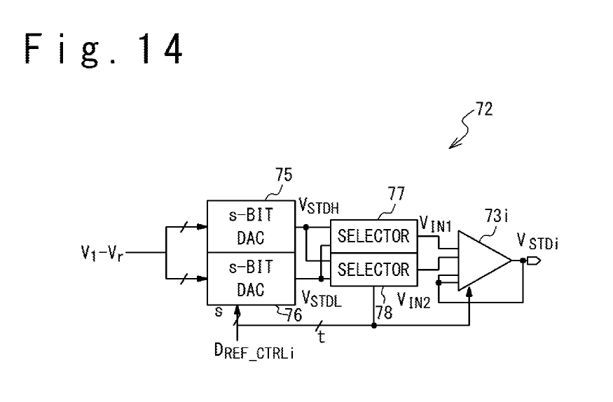

The semiconductor circuit 10 of this embodiment may be used as the tournament circuit 72 and preamplifiers 73₁ to 73ₚ of the gamma circuit 70. FIG. 14 is a circuit diagram illustrating the configuration of the tournament circuit 72 in this case. Illustrated in FIG. 14 is the configuration of a circuit part of the tournament circuit 72 associated with one preamplifier 73ᵢ.

The tournament circuit 72 includes DA converters 75, 76 and selectors 77 and 78. The preamplifier 73ᵢ is connected to the outputs of the selectors 77 and 78 and configured similarly to the differential amplifier circuit 5 illustrated in FIG. 2. It should be noted that the configuration illustrated in FIG. 14 is same as that illustrated in FIG. 1. The DA converters 75, 76, the selectors 77, 78 and the preamplifier 73ᵢ operate in the same way as the DA converters 1, 2, the selectors 3, 4 and the differential amplifier circuit 5, respectively.

More specifically, the DA converters 75 and 76 are each configured to select any one of the voltages V₁ to Vᵣ received from the resistor string 71 in response to the upper s bits of the reference voltage control data D_{REF}_{_}_{CTRLi} and output the selected voltage, where r, which is the number of the voltages V₁ to Vᵣ supplied to the DA converters 75 and 76, is 2^{s}+1. In the following, the voltage selected and output by the DA converter 75 is referred to as the selected voltage V_{STDH} and the voltage selected and output by the DA converter 76 is referred to as the selected voltage V_{STDL}. It should be noted that the selected voltages V_{STDH} and V_{STDH} selected by the DA converters 75 and 76 are different from each other and the selected voltage V_{STDH} is higher than the selected voltage V_{STDL}.

The selectors 77 and 78 each select one of the selected voltages V_{STDH} and V_{STDH} in response to the lower t bits of the reference voltage control data D_{REF}_{_}_{CTRLi} and output the selected voltage. The voltage selected and output by the selector 77 is used as the selected input voltage V_{IN1} supplied to the preamplifier 73ᵢ and the voltage selected and output by the selector 78 is used as the selected input voltage V_{IN2} supplied to the preamplifier 73ᵢ.

The preamplifier 73ᵢ is configured to receive the selected input voltages V_{IN1} and V_{IN2} from the selectors 77 and 78 and generate the standard voltage V_{STDi} from the selected input voltages V_{IN1} and V_{IN2}. The preamplifier 73ᵢ is configured similarly to the above-described differential amplifier circuit 5 and the voltage level of the standard voltage V_{STDi} is adjusted in response to the value of the lower t bits of the reference voltage control data D_{REF}_{_}_{CTRLi}.

The configurations of the tournament circuit 72 and the preamplifier 73ᵢ illustrated in FIG. 14 effectively reduce the number r of the voltages V₁ to Vᵣ down to 2^{s}+1, while offering digital-analog conversion of a resolution of (s+t) bits.

Although various embodiments of the present disclosure have been specifically described in the above, a person skilled in the art would appreciate that the present disclosure may be implemented with various modifications.

What is claimed is:

1. A semiconductor circuit, comprising:
a first DA converter configured to receive a plurality of reference voltages and select a first reference voltage from the plurality of reference voltages in response to upper m bits of (m+n)-bit input digital data;
a second DA converter configured to receive the plurality of reference voltages and select a second reference voltage from the plurality of reference voltages in response to the upper m bits of the input digital data so that the second reference voltage is lower than the first reference voltage;
a select circuitry configured to receive the first and second reference voltages and output first to N-th selected input voltages in response to lower n bits of the input digital data for N being an integer two or more, wherein each of the first to N-th selected input voltages is selected as one of the first and second reference voltages;
first to N-th differential input stages;
first and second drain interconnections;
an output stage configured to output an analog output voltage to an output node in response to currents flowing through the first and second drain interconnections; and
a first tail current source,
wherein each of the first to N-th differential input stages includes:
a first MISFET of a first conductivity type, having a source connected to a first node and a drain connected to the first drain interconnection; and
a second MISFET of the first conductivity type, having a source connected to the first node and a drain connected to the second drain interconnection,
wherein the i-th selected input voltage of the first to N-th selected input voltages is supplied to the gate of the first MISFET of the i-th differential input stage of the first to N-th differential input stages, where i is any integer from one to N,
wherein the gate of the second MISFET of each of the first to N-th differential input stages is connected to the output node,
wherein the first tail current source is configured to generate a first tail current flowing through the first node of each of the first to N-th differential input stages, and
wherein the first tail current source controls a current level of the first tail current generated in each of the first to N-th differential input stages in response to lower n bits of the input digital data.

2. The semiconductor circuit according to claim 1, further comprising:
third and fourth drain interconnections; and
a second tail current source,
wherein each of the first to N-th differential input stages further includes:
a third MISFET of a second conductivity type complementary to the first conductivity type, having a source connected to a second node and a drain connected to the third drain interconnection; and
a fourth MISFET of the second conductivity type, having a source connected to the second node and a drain connected to the fourth drain interconnection,
wherein the i-th selected input voltage is supplied to the gate of the third MISFET of the i-th differential input stage,
wherein the gate of the fourth MISFET of each of the first to N-th differential input stages is connected to the output node,
wherein the second tail current source is configured to generate a second tail current flowing through the second node of each of the first to N-th differential input stages,
wherein the second tail current source controls a current level of the second tail current generated in each of the first to N-th differential input stages in response to the lower n bits of the input digital data.

3. The semiconductor circuit according to claim 1, wherein the first tail current source includes:
a plurality of first constant current sources; and
a first switch circuit configured to connect each of the plurality of first constant current sources to a selected one of the first nodes of the first to N-th differential input stages in response to the lower bits of the input digital data.

4. The semiconductor circuit according to claim 2, wherein the first tail current source includes:
a plurality of first constant current sources; and
a first switch circuit configured to connect each of the plurality of first constant current sources to a selected one of the first nodes of the first to N-th differential input stages in response to the lower bits of the input digital data, and
wherein the second tail current source includes:
a plurality of second constant current sources; and
a second switch circuit configured to connect each of the plurality of second constant current sources to a selected one of the second nodes of the first to N-th differential input stages in response to the lower bits of the input digital data.

5. The semiconductor circuit according to claim 3, wherein the plurality of first constant current sources are configured to generate constant currents having the same current level.

6. The semiconductor circuit according to claim 4, wherein the plurality of first constant current sources are configured to generate constant currents having the same current level, and wherein the plurality of second constant current sources are configured to generate constant currents having the same current level.

7. A semiconductor circuit, comprising:
a first DA converter configured to receive a plurality of reference voltages and select a first reference voltage from the plurality of reference voltages in response to upper m bits of (m+n)-bit input digital data;
a second DA converter configured to receive the plurality of reference voltages and select a second reference voltage from the plurality of reference voltages in response to the upper m bits of the input digital data so that the second reference voltage is lower than the first reference voltage;
a select circuitry configured to receive the first and second reference voltages and output first to N-th selected input voltages in response to lower n bits of the input digital data for N being an integer two or more, wherein each of the first to N-th selected input voltages is selected as one of the first and second reference voltages;
first to N-th differential input stages;
first to fourth drain interconnections;
an output stage configured to output an analog output voltage to an output node in response to currents flowing through the first to fourth drain interconnections; and
first and second tail current sources,
wherein the first to N-th selected input voltages are supplied to the first to N-th differential input stages, respectively,
wherein at least one of the first to N-th differential input stages includes:
a first MISFET of a first conductivity type, having a source connected to a first node and a drain connected to the first drain interconnection;
a second MISFET of the first conductivity type, having a source connected to the first node and a drain connected to the second drain interconnection;
wherein a remaining one(s) of the first to N-th differential input stages includes:
a third MISFET of a second conductivity type complementary to the first conductivity type, having a source connected to a second node and a drain connected to the third drain interconnection;
a second MISFET of the second conductivity type, having a source connected to the second node and a drain connected to the fourth drain interconnection;
wherein a corresponding one of the first to N-th selected input voltages is supplied to the gate of the first MISFET of the at least one of the first to N-th differential input stage,
wherein the gate of the second MISFET of the at least one of the first to N-th differential input stage is connected to the output node,
wherein a corresponding one of the first to N-th selected input voltages is supplied to the gate of the third MISFET of the remaining one(s) of the first to N-th differential input stage,
wherein the gate of the fourth MISFET of the remaining one(s) of the first to N-th differential input stage is connected to the output node,
wherein the first tail current source is configured to generate a first tail current flowing through the first node of the at least one of the first to N-th differential input stages, and
wherein the first tail current source controls a current level of the first tail current generated through the first node of the at least one of the first to N-th differential input stages in response to lower n bits of the input digital data,
wherein the second tail current source is configured to generate a second tail current flowing through the second node of the remaining one(s) of the first to N-th differential input stages, and
wherein the second tail current source controls a current level of the second tail current generated through the second node of the remaining one(s) of the first to N-th differential input stages in response to lower n bits of the input digital data,
wherein the at least one of the first to N-th differential input stages does not include a differential pair including MISFETs of the second conductivity type, and
wherein the remaining one(s) of the first to N-th differential input stages does not include a differential pair including MISFETs of the first conductivity type.

8. A display driver adapted to drive a source line of a display panel in response to image data, the driver comprising:
a source output to be connected to the source line;
a first DA converter configured to receive a plurality of reference voltages and select a first reference voltage from the plurality of reference voltages in response to upper m bits of (m+n)-bit image data;
a second DA converter configured to receive the plurality of reference voltages and select a second reference voltage from the plurality of reference voltages in response to the upper m bits of the image data so that the second reference voltage is lower than the first reference voltage;
a select circuitry configured to receive the first and second reference voltages and output first to N-th selected input voltages in response to lower n bits of the image data for N being an integer two or more, wherein each of the first to N-th selected input voltages is selected as one of the first and second reference voltages;
first to N-th differential input stages;
first and second drain interconnections;
an output stage configured to output an analog output voltage to an output node connected to the source output in response to currents flowing through the first and second drain interconnections; and
a first tail current source,
wherein each of the first to N-th differential input stages includes:
a first MISFET of a first conductivity type, having a source connected to a first node and a drain connected to the first drain interconnection;
a second MISFET of the first conductivity type, having a source connected to the first node and a drain connected to the second drain interconnection;
wherein the i-th selected input voltage of the first to N-th selected input voltages is supplied to the gate of the first MISFET of the i-th differential input stage of the first to N-th differential input stages, where i is any integer from one to N,
wherein the gate of the second MISFET of each of the first to N-th differential input stages is connected to the output node,
wherein the first tail current source is configured to generate a first tail current flowing through the first node of each of the first to N-th differential input stages, and
wherein the first tail current source controls a current level of the first tail current generated in each of the first to N-th differential input stages in response to lower n bits of the image data.

9. The display driver according to claim 8, further comprising:
third and fourth drain interconnections; and
a second tail current source,
wherein each of the first to N-th differential input stages further includes:
a third MISFET of a second conductivity type complementary to the first conductivity type, having a source connected to a second node and a drain connected to the third drain interconnection; and
a fourth MISFET of the second conductivity type complementary to the first conductivity type, having a source connected to the second node and a drain connected to the fourth drain interconnection,
wherein the i-th selected input voltage is supplied to the gate of the third MISFET of the i-th differential input stage,
wherein the gate of the fourth MISFET of each of the first to N-th differential input stages is connected to the output node,
wherein the second tail current source is configured to generate a second tail current flowing through the second node of each of the first to N-th differential input stages, and
wherein the second tail current source controls a current level of the second tail current generated in each of the first to N-th differential input stages in response to the lower n bits of the image data.

10. A display driver for driving source lines of a display panel in response to image data, the driver comprising:
a reference voltage generator circuit configured to generate a plurality of reference voltages and
a drive circuitry configured to receive the image data and output source voltages having voltage levels corresponding to the image data to the source lines by using the plurality of reference voltages,
wherein the reference voltage generator circuit includes:
a resistor string;
a first DA converter configured to receive a plurality of voltages and select a first selected voltage from the plurality of voltages in response to upper m bits of (m+n)-bit input digital data;
a second DA converter configured to receive the plurality of voltages and select a second selected voltage from the plurality of voltages in response to the upper m bits of the input digital data so that the second reference voltage is lower than the first reference voltage;
a select circuitry configured to receive the first and second selected voltages and output first to N-th selected input voltages in response to lower n bits of the input digital data for N being an integer two or more, wherein each of the first to N-th selected input voltages is selected as one of the first and second selected voltages;
a preamplifier configured to receive the first to N-th selected input voltages and supply a standard voltage to the resistor string in response to the first to N-th selected input voltages,
wherein the plurality of reference voltages are generated from voltages obtained from a plurality of positions of the resistor string,
wherein the preamplifier includes:
first to N-th differential input stages;
first and second drain interconnections;
an output stage configured to output the standard voltage to an output node connected to the resistor string in response to currents flowing through the first and second drain interconnections; and
a first tail current source,
wherein each of the first to N-th differential input stages includes:
a first MISFET of a first conductivity type, having a source connected to a first node and a drain connected to the first drain interconnection;
a second MISFET of the first conductivity type, having a source connected to the first node and a drain connected to the second drain interconnection;
wherein the i-th selected input voltage of the first to N-th selected input voltages is supplied to the gate of the first MISFET of the i-th differential input stage of the first to N-th differential input stages, where i is any integer from one to N,
wherein the gate of the second MISFET of each of the first to N-th differential input stages is connected to the output node,
wherein the first tail current source is configured to generate a first tail current flowing through the first node of each of the first to N-th differential input stages, and
wherein the first tail current source controls a current level of the first tail current generated in each of the first to N-th differential input stages in response to lower n bits of the input digital data.

11. The display driver according to claim 10, wherein the preamplifier further includes:
third and fourth drain interconnections; and
a second tail current source,
wherein each of the first to N-th differential input stages further includes:
a third MISFET of a second conductivity type complementary to the first conductivity type, having a source connected to a second node and a drain connected to the third drain interconnection; and
a fourth MISFET of the second conductivity type complementary to the first conductivity type, having a source connected to the second node and a drain connected to the fourth drain interconnection,
wherein the i-th selected input voltage is supplied to the gate of the third MISFET of the i-th differential input stage,
wherein the gate of the fourth MISFET of each of the first to N-th differential input stages is connected to the output node,
wherein the second tail current source is configured to generate a second tail current flowing through the second node of each of the first to N-th differential input stages,
wherein the second tail current source controls a current level of the second tail current generated in each of the first to N-th differential input stages in response to the lower n bits of the input digital data.
